(19) United States
(12) Patent Application Publication
(10) Pub. No.: US 2019/0280141 A1
(43) Pub. Date: Sep. 12, 2019

(54) PHOTOELECTRIC CONVERSION ELEMENT, PHOTOELECTRIC CONVERSION MODULE, AND ELECTRONIC DEVICE

(71) Applicant: SEIKO EPSON CORPORATION, Tokyo (JP)

(72) Inventors: Masahiro TAKEUCHI, Chino-shi (JP); Yukimune WATANABE, Hokuto-shi (JP); Daisuke NAGANO, Matsumoto-shi (JP); Masahiro FURUSAWA, Chino-shi (JP)

(73) Assignee: SEIKO EPSON CORPORATION, Tokyo (JP)

(21) Appl. No.: 16/293,851

(22) Filed: Mar. 6, 2019

(30) Foreign Application Priority Data
Mar. 7, 2018 (JP) 2018-040460

(51) Int. Cl. H01L 31/05; H01L 31/02; H01L 31/0236; H01L 31/0352; H01L 31/053

(52) U.S. Cl. CPC H01L 31/0516; H01L 31/0201; G04G 19/00; H01L 31/035281; H01L 31/053; H01L 31/02363

(57) ABSTRACT

A photoelectric conversion element includes a photoelectric conversion layer that has a p-type impurity region and an n-type impurity region, an insulating layer that overlaps with the p-type impurity region and the n-type impurity region and has a groove outside the p-type impurity region and the n-type impurity region in a plan view of a main surface of the photoelectric conversion layer, a p-type electrode electrically connected to the p-type impurity region, an n-type electrode electrically connected to the n-type impurity region, and a barrier layer that has a lower moisture permeability than the insulating layer, in the groove.

### BACKGROUND

### 1. Technical Field

The present invention relates to a photoelectric conversion element, a photoelectric conversion module, and an electronic device.

### 2. Related Art

In recent years, it has been studied to mount a solar cell module (photoelectric conversion module) on a mobile device such as a wristwatch, a wearable terminal, or a mobile phone terminal.

Because the mobile device is often used outdoors, moisture resistance is taken into account when designing the same. Therefore, it is required that the solar cell module mounted on the mobile device also has the increased moisture resistance.

For example, JP-A-2015-177169 discloses a solar cell module having a wiring sheet, a photoelectric conversion element provided on one surface of the wiring sheet, and a back sheet attached to the other surface of the wiring sheet through an adhesive layer. With this structure, since the adhesive layer can be thinned, moisture can hardly penetrate the solar cell module. Therefore, a solar cell module having high moisture resistance (resistance against humidity) can be obtained.

However, it is necessary for these sheets to be sufficiently larger than a photoelectric conversion element in order to cover a photoelectric conversion element using a wiring sheet or a back sheet. Therefore, there is a problem that it is difficult to reduce size of a solar cell module. Therefore, there is a need for attain a solar cell module with high moisture resistance, without increasing the size of the solar cell module.

### SUMMARY

An advantage of some aspects of the invention is to solve the problems described above, and the invention can be implemented as the following application example.

A photoelectric conversion element according to an application example includes a semiconductor substrate, a first conductivity type impurity region and a second conductivity type impurity region formed in the semiconductor substrate, an insulating layer provided to overlap the first conductivity type impurity region and the second conductivity type impurity region when the main surface of the semiconductor substrate is seen in a plan view, a first electrode electrically connected to the first conductivity type impurity region, a second electrode electrically connected to the second conductivity type impurity region, a groove formed in the insulating layer and located outside the first conductivity type impurity region and the second conductivity type impurity region when the main surface of the semiconductor substrate is seen in a plan view, and a barrier layer provided in the groove and having a lower moisture permeability than the insulating layer.

### BRIEF DESCRIPTION OF THE DRAWINGS

The invention will be described with reference to the accompanying drawings, wherein like numbers reference like elements.

FIG. 1 is a perspective view showing an electronic timepiece to which an embodiment of an electronic device of the invention is applied.

FIG. 2 is a perspective view showing an electronic timepiece to which an embodiment of an electronic device according to the invention is applied.

FIG. 3 is a plan view showing the electronic timepiece shown in FIGS. 1 and 2.

FIG. 4 is a longitudinal sectional view showing the electronic timepiece shown in FIGS. 1 and 2.

FIG. 5 is a plan view showing only a photoelectric conversion module of the electronic timepiece shown in FIG. 4.

FIG. 6 is an exploded perspective view showing the photoelectric conversion module shown in FIG. 5.

FIG. 7 is an exploded sectional view showing the photoelectric conversion module shown in FIG. 5.

FIG. 8 is a plan view showing an electrode plane of the photoelectric conversion element shown in FIG. 6.

FIG. 9 is a view showing selectively finger electrodes in the plan view shown in FIG. 8.

FIG. 10 is a view showing selectively bus bar electrodes and electrode pads in the plan view shown in FIG. 8.

FIG. 11 is an enlarged view of the portion A shown in FIG. 8.

FIG. 12 is a partially enlarged view showing a further enlarged view of FIG. 11.

FIG. 13 is a cross-sectional view showing a photoelectric conversion module according to a second embodiment.

FIG. 14 is a plan view showing a photoelectric conversion module according to a third embodiment.

FIG. 15 is a cross-sectional view showing a photoelectric conversion module according to a fourth embodiment.

FIG. 16 is a plan view showing the photoelectric conversion module shown in FIG. 15.

FIG. 17 is a cross-sectional view showing a photoelectric conversion module according to a fifth embodiment.

FIG. 18 is a plan view showing the photoelectric conversion element shown in FIG. 17.

FIG. 19 is a plan view showing a first modification of the photoelectric conversion element shown in FIG. 18.

FIG. 20 is a plan view showing a portion of a second modification of the photoelectric conversion element shown in FIG. 18.

FIG. 21 is a view for explaining an example of a method for manufacturing the photoelectric conversion module shown in FIG. 7.

FIG. 22 is a view for explaining an example of a method for manufacturing the photoelectric conversion module shown in FIG. 7.

### DESCRIPTION OF EXEMPLARY EMBODIMENTS

Hereinafter, a photoelectric conversion element, a photoelectric conversion module, and an electronic device according to the invention will be described in detail based on preferred embodiments shown in the attached drawings.

### Electronic Device

First, an electronic timepiece to which an embodiment of the electronic device according to the invention is applied will be described. The electronic timepiece is configured such that, when the light receiving surface of the electronic timepiece is irradiated with light, the electronic timepiece generates electric power (by photoelectric conversion) with embedded solar cells (photoelectric conversion module) for utilization of the electric power obtained by such electricity generation as the driving power.

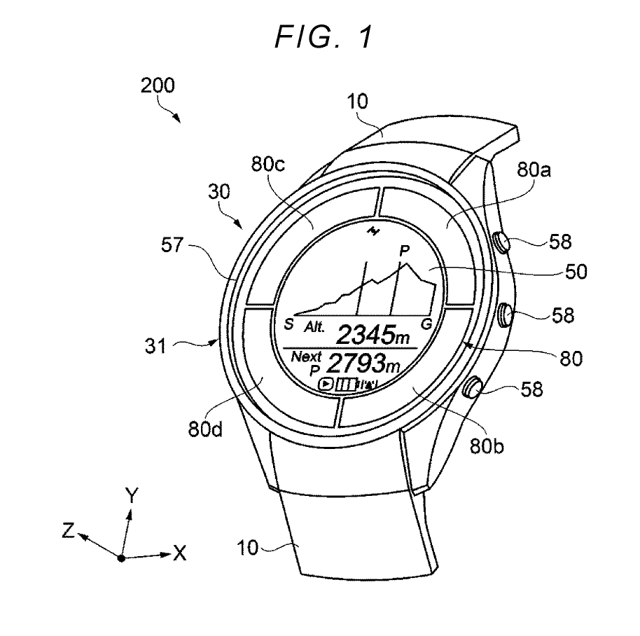

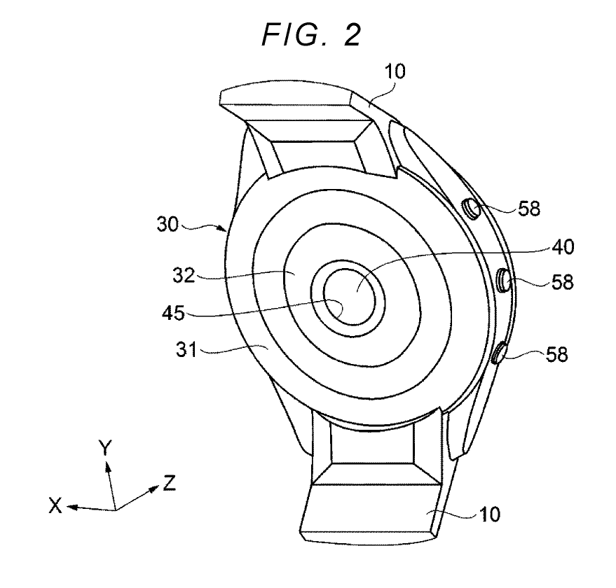

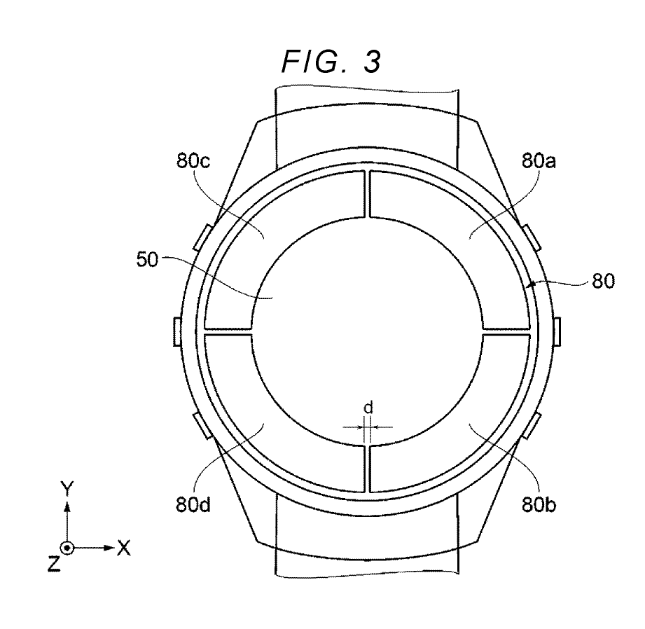

FIGS. 1 and 2 are perspective views each showing an electronic timepiece to which an embodiment of an electronic device according to the invention is applied. FIG. 1 is a perspective view showing an external appearance of the electronic timepiece as viewed from the front side (light receiving surface side), and FIG. 2 is a perspective view showing the external appearance of the electronic timepiece as viewed from the back side. In addition, FIG. 3 is a plan view showing the electronic timepiece shown in FIGS. 1 and 2, and FIG. 4 is a longitudinal sectional view showing the electronic timepiece shown in FIGS. 1 and 2.

The electronic timepiece 200 includes a case 31, a solar cell 80 (photoelectric conversion module), a device main body 30 including a display unit 50 and a light sensor 40, and two bands 10 attached to the case 31.

In the following description, a direction axis extending in a direction orthogonal to the light receiving surface of the solar cell 80 is defined as a Z axis. Further, the direction from the back side to the front side of the electronic timepiece is defined as “+z direction”, and the opposite direction is defined as “−Z direction”.

Meanwhile, two axes orthogonal to the Z axis are defined as “X-axis” and “Y-axis”. Among them, the direction axis connecting the two bands 10 to each other is defined as the Y-axis, and the direction axis orthogonal to the Y-axis is defined as the X-axis. In addition, the upward direction of the display unit 50 is defined as “+Y direction”, and the downward direction of the display unit 50 is defined as “−Y direction”. Further, when the light receiving surface of the solar cell 80 is seen in a plan view, the rightward direction is defined as “+X direction” and the leftward direction is defined as “−X direction”.

### Device Main Body

Hereinafter, the configuration of the electronic timepiece 200 will be sequentially described. A device main body 30 has a housing including a case 31 with openings on a front side and a back side, a windproof plate 55 provided to close the opening on the front side, a bezel 57 provided to cover a surface of the case 31 and a side surface of the windproof plate 55, and a transparent cover 44 provided to close the opening on the back side. The housing accommodates various components described below.

The housing includes the case 31 having an annular shape, an opening 35 in the front side that can fittingly receive the windproof plate 55, and an opening (measuring window 45) in the back side that can fittingly receive the transparent cover 44.

In addition, the case 31 includes a protruding portion 32 protruding from a portion of the back side. A top portion of the protruding portion 32 has an opening, and a transparent cover 44 is fitted in the opening, with a portion of the transparent cover 44 protruding from the opening.

Examples of a constituent material for the case 31 include a resin material, a ceramic material, and the like as well as a metal material such as stainless steel and titanium alloy. In addition, the case 31 may be an assembly of a plurality of parts, which may have different constituent materials from each other.

In addition, a plurality of operation sections 58 (operation buttons) are provided on an outer side surface of the case 31. Further, a protrusion 34 protruding in the +Z direction is formed on an outer edge of the opening 35 provided on the front side of the case 31. Then, the bezel 57 is provided in an annular shape to cover the protrusion 34.

Further, the windproof plate 55 is provided inside the bezel 57. A side surface of the windproof plate 55 and the bezel 57 are bonded by a bonding member 56 such as a packing or an adhesive.

Examples of a constituent material of the windproof plate 55 and the transparent cover 44 include a glass material, a ceramic material, a resin material, and the like. In addition, the windproof plate 55 has translucency, and the content displayed on the display unit 50 can be visually recognized through the windproof plate 55. Further, the transparent cover 44 also has the translucency, and the light sensor 40 can serve as a biological information measuring unit.

Further, an internal space 36 of the housing is a closed space capable of housing various components described below.

The device main body 30 includes therein components for housing in the internal space 36, which are a circuit substrate 20, an electronic compass 22 (geomagnetism sensor), an acceleration sensor 23, a GPS antenna 28, a light sensor 40, an electro-optical panel 60 and an illumination unit 61 constituting the display unit 50, a secondary battery 70, and a solar cell 80. In addition, the device main body 30 may include various sensors such as a pressure sensor for calculating the altitude, the water depth, or the like, a temperature sensor for measuring the temperature, an angular velocity sensor, a vibrator, and the like in addition to the above components.

The circuit substrate 20 includes wiring for electrically connecting the components described above to each other. In addition, a Central Processing Unit (CPU) 21 including a control circuit, a drive circuit and the like for controlling the operation of the components described above and other circuit elements 24 are mounted on the circuit substrate 20.

In addition, the solar cell 80, the electro-optical panel 60, the circuit substrate 20, and the light sensor 40 are disposed in this order from the windproof plate 55 side. Thereby, the solar cell 80 is disposed close to the windproof plate 55, and a large amount of external light is efficiently impinged on the solar cell 80. As a result, the photoelectric conversion efficiency of the solar cell 80 can be maximized.

Hereinafter, components housed in the device main body 30 will be described in more detail. The end portion of the circuit substrate 20 is attached to the case 31 through the circuit case 75.

In addition, an interconnect wiring portion 63 and ab interconnect wiring portion 81 are electrically connected to the circuit substrate 20. Among them, the circuit substrate 20 and the electro-optical panel 60 are electrically connected through the interconnect wiring portion 63. In addition, the circuit substrate 20 and the solar cell 80 are electrically connected through the interconnect wiring portion 81. These interconnect wiring portions 63 and 81 are provided on a flexible circuit substrate and are efficiently routed in the gaps of the internal space 36, for example.

The electronic compass 22 and the acceleration sensor 23 can measure information on the movement of the user's body wearing the electronic timepiece 200. The electronic compass 22 and the acceleration sensor 23 output signals that vary according to a movement of the user's body and transmit the same to the CPU 21.

The CPU 21 includes a circuit for controlling a GPS receiving unit (not shown) including the GPS antenna 28, a circuit for driving the light sensor 40 to measure pulse waves of the user, and the like, a circuit for driving the display unit 50, a circuit for controlling power generation of the solar cell 80, and the like.

The GPS antenna 28 receives radio waves from a plurality of positioning information satellites. In addition, the device main body 30 includes a signal processing unit (not shown). The signal processing unit calculates positioning based on a plurality of positioning signals received by the GPS antenna 28 and acquires time and position information. The signal processing unit transmits these pieces of information to the CPU 21.

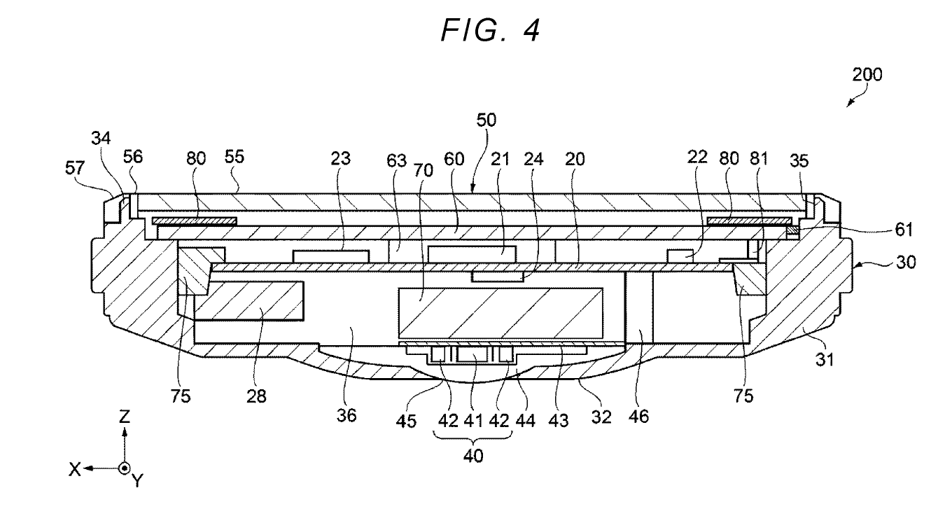

The light sensor 40 is a biological information measuring unit that measures a pulse wave or the like of the user. The light sensor 40 shown in FIG. 4 is a photoelectric sensor including a light receiving unit 41, a plurality of light emitting units 42 provided outside the light receiving unit 41, and a sensor substrate 43 on which the light receiving unit 41 and the light emitting unit 42 are mounted. In addition, the light receiving unit 41 and the light emitting unit 42 face the measuring window 45 of the case 31 through the transparent cover 44 described above. In addition, the circuit substrate 20 and the light sensor 40 are electrically connected through the interconnect wiring portion 46 included in the device main body 30.

Such a light sensor 40 emits a light exited from the light emitting unit 42 onto a subject (for example, the skin of the user) and receives the reflected light with the light receiving unit 41, and thus measures the pulse wave. The light sensor 40 transmits the information of the detected pulse wave to the CPU 21.

Another sensor such as an electrocardiograph or an ultrasonic sensor may be used in place of the photoelectric sensor.

In addition, the device main body 30 includes a communication unit (not shown). The communication unit transmits to the outside various kinds of information acquired by the device main body 30, stored information, a result calculated by the CPU 21, and the like.

The display unit 50 allows the user to visually recognize the display content of the electro-optical panel 60 through the windproof plate 55. Thus, for example, the information acquired from the components described above can be displayed on the display unit 50 as texts or images so that the user can recognize the information.

Examples of the electro-optical panel 60 include a liquid crystal display device, an organic electroluminescence (EL) display device, an electrophoretic display device, a light emitting diode (LED) display device, and the like.

In FIG. 4, the electro-optical panel 60 is illustrated as a reflective display device (for example, a reflective liquid crystal display device, an electrophoretic display device, and the like) as an example. Therefore, the display unit 50 includes the illumination unit 61 provided on the light incident surface of the light guide plate (not shown) included in the electro-optical panel 60. Examples of the illumination unit 61 include an LED element. The illumination unit 61 and the light guide plate serve as a front light of the reflective display device.

When the electro-optical panel 60 is a transmissive display device (e.g., a transmissive liquid crystal display device, and the like), a backlight may be provided in place of the front light.

In addition, when the electro-optical panel 60 is a self-emissive display device (for example, an organic EL display device, an LED display device or the like), or when the electro-optical panel 60 is not a self-emissive display device but is a display device utilizing external light, the front light and backlight can be omitted.

The secondary battery 70 is connected to the circuit substrate 20 through a wiring (not shown). Thus, the electric power outputted from the secondary battery 70 can be used for driving the components described above. In addition, the secondary battery 70 can be charged with power generated by the solar cell 80.

The electronic timepiece 200 has been described above, but, the embodiment of the electronic device according to the invention is not limited to the electronic timepiece, and may be a mobile phone terminal, a smartphone, a tablet terminal, a wearable terminal, a camera, or the like, for example.

### Solar Cell

### First Embodiment

Next, a solar cell 80 to which the first embodiment of the photoelectric conversion module according to the invention is applied will be described in detail.

The solar cell 80 is a photoelectric conversion module that converts light energy into electric energy.

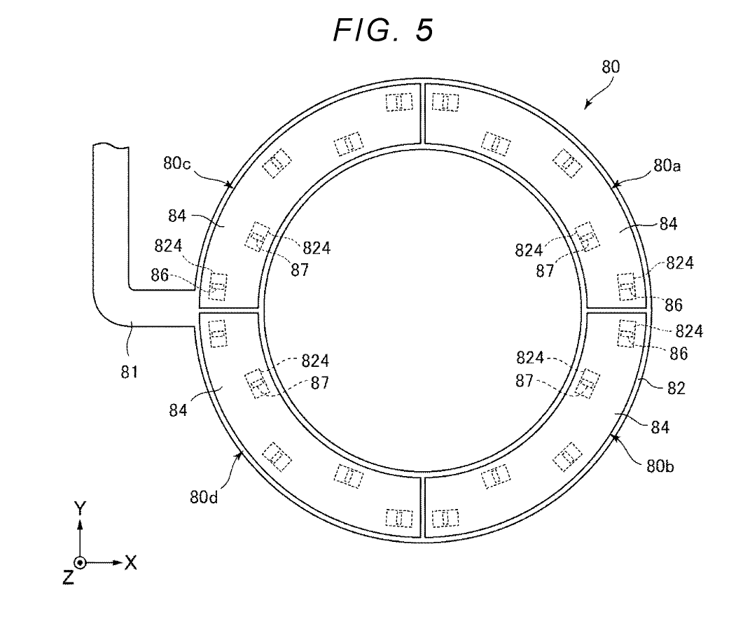

FIG. 5 is a plan view showing only the solar cell 80 of the electronic timepiece 200 shown in FIG. 4.

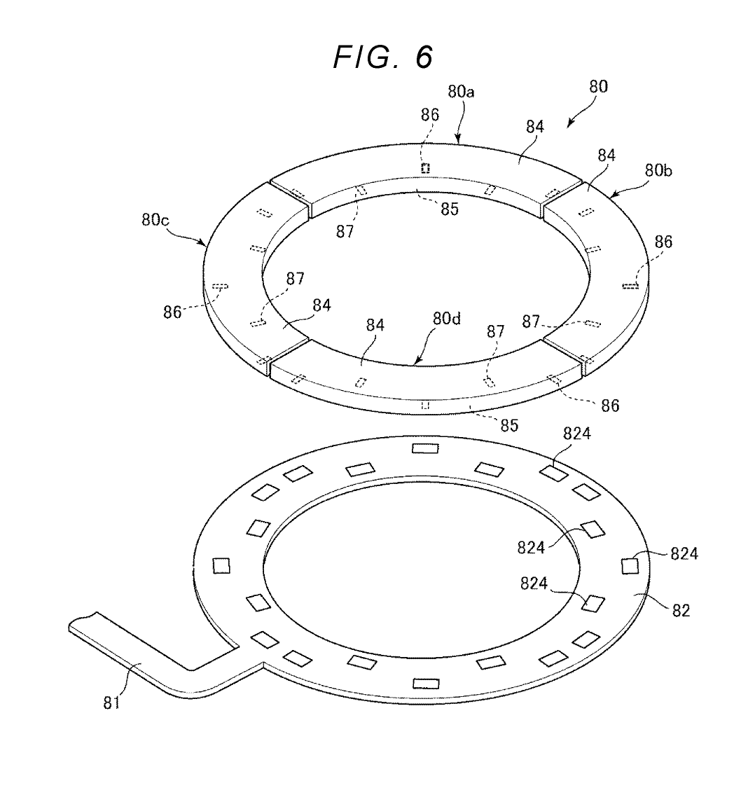

In addition, FIG. 6 is an exploded perspective view showing the solar cell 80 shown in FIG. 5.

The solar cell 80 (photoelectric conversion module) shown in FIG. 5 is provided between the windproof plate 55 and the electro-optical panel 60 and includes four cells 80a, 80b, 80c, and 80d (photoelectric conversion elements), and a wiring substrate 82 electrically connected to four cells 80a, 80b, 80c, and 80d.

Each of the cells 80a, 80b, 80c, and 80d is in a plate shape, and main surfaces thereof face the Z-axis direction. In addition, the main surface facing the windproof plate 55 of the main surfaces of the cells 80a, 80b, 80c, and 80d is the light receiving surface 84 that receives external light. Meanwhile, the main surface facing the wiring substrate 82 is an electrode plane 85 that is provided with electrode pads for transmitting the generated electric power.

When seen in a plan view, the shape of the solar cell 80 shown in FIG. 5 is an annular shape. In other words, the four cells 80a, 80b, 80c, and 80d are arranged with a slight gap formed therebetween, such that the overall plan view shape is a ring in which an inner periphery shape (inner shape) and an outer periphery shape (outer shape) are each circular in shape.

Meanwhile, since the opening 35 of the case 31 described above is circular in shape, the inner periphery thereof includes a curved portion.

Such electronic timepiece 200 can arrange the solar cell 80 efficiently while ensuring space of the main parts such as the display unit 50 with respect to the case 31 having a circular opening 35. Accordingly, since the solar cell 80 can be arranged close to the windproof plate 55, the photoelectric conversion efficiency of the solar cell 80 can be sufficiently enhanced. Meanwhile, the arrangement space of the display unit 50 can be ensured in the center portion of the opening 35, so that the visibility of the display unit 50 is improved and the balance of the arrangement of the display unit 50 and the solar cell 80 is also improved. As a result, the electronic timepiece 200 having both the photoelectric conversion efficiency of the solar cell 80 and the overall design can be obtained.

It should be noted that the opening 35 (the inner periphery) of the case 31 may include a straight portion and a curved portion, for example.

In addition, the “outer periphery of the solar cell 80” refers to a portion of an outline of the solar cell 80 facing toward the outside of the opening 35, and the “inner periphery of the solar cell 80” refers to a portion of the outline of the solar cell 80 facing toward the center side of the opening 35.

In addition, in the four cells 80a, 80b, 80c, and 80d, the inner periphery and the outer periphery are preferably apart of a circle (a concentric circle) having the same center as each other. In other words, when the assembly of the four cells 80a, 80b, 80c, and 80d forms an annular shape, it is preferable that the inner and outer circles of the circle are concentric. Thereby, it is possible to realize the electronic timepiece 200 having a particularly high design property.

As shown in FIG. 3, a display unit 50 (electro-optical panel 60) is provided on the inner periphery side of the solar cell 80, and the outer shape of the display unit 50 is designed along the inner periphery of the solar cell 80. In other words, the electronic timepiece 200 has the electro-optical panel 60 including the outer shape designed along the inner periphery of the solar cell 80. This arrangement allows the outer shape of the display unit 50 arranged inside the solar cell 80 to be a circular shape, thereby realizing the electronic timepiece 200 with high design property.

In addition, at least a part of the solar cell 80 is disposed to overlap with the outside of the pixel region of the electro-optical panel 60. Thus, for example, if the display unit 50 (electro-optical panel 60) is disposed at a position farther than the solar cell 80 when the electronic timepiece 200 is viewed in the direction facing the light receiving surface 84 of the solar cell 80, the solar cell 80 can serve as a so-called parting plate covering the outside of the pixel region of the electro-optical panel 60.

In this embodiment, the solar cell 80 is configured by an assembly of the four cells 80a, 80b, 80c, and 80d, but the number of cells may be one, or may be any number of two or more.

In addition, in the present embodiment, the shape of the solar cell 80 is an annular shape in a plan view, but may be a multi-annular shape.

In addition, one or more of the four cells 80a, 80b, 80c, and 80d may be omitted, and the shapes of the cells may be different from each other.

In addition, the semiconductor substrate included in the solar cell 80 may have amorphous properties, although it is preferably crystalline. The crystallinity herein refers to mono-crystallinity or poly-crystallinity. When including a semiconductor substrate having such crystallinity, the solar cell 80 can obtain a higher photoelectric conversion efficiency, as compared with an example of including a semiconductor substrate having amorphousness. The solar cell 80 enables to further reduce the area for generating the same electric power. Therefore, by including a semiconductor substrate having crystallinity, more sophisticated electronic timepiece 200 is obtained, which can achieve both the photoelectric conversion efficiency and the design.

In particular, it is preferable that the semiconductor substrate has mono-crystallinity. Thereby, the photoelectric conversion efficiency of the solar cell 80 is particularly enhanced. Accordingly, it is possible to maximize compatibility between photoelectric conversion efficiency and design property. In addition, in particular, it is possible to further enhance the design of the electronic timepiece 200 by saving the space of the solar cell 80. Further, there is also an advantage that the photoelectric conversion efficiency is hardly lowered even with a low illuminance light such as indoor light.

Examples of the semiconductor substrate include other compound semiconductor substrates (for example, a GaAs substrate) in addition to a silicon substrate.

It should be noted that the expression “having mono-crystallinity” refers to not only an example where the semiconductor substrate is entirely mono-crystalline, but also an example where it is partially poly-crystalline or amorphous. In the latter's case, it is preferable that the volume of the mono-crystalline is relatively large (for example, equal to or greater than 90 vol % of the whole).

In addition, the solar cell 80 is preferably a back electrode type. Specifically, as shown in FIG. 6, electrode pads 86 and 87 (connection portions) are provided on the electrode planes 85 of the four cells 80a, 80b, 80c, and 80d, respectively. Among them, the electrode pad 86 is a positive electrode, and on the other hand, the electrode pad 87 is a negative electrode. Therefore, power can be transmitted from the electrode pad 86 and the electrode pad 87 through the wiring.

In the back electrode type, all the electrode pads can be arranged on the electrode plane 85 (back side) side.

Therefore, it is possible to maximize the light receiving surface 84, and it is also possible to increase the amount of generated power by way of the maximization of the light receiving area. In addition, it is possible to prevent the deterioration of design by providing the electrode pad on the light receiving surface 84 side. Therefore, the design of the electronic timepiece 200 can be further enhanced.

In addition, as shown in FIG. 5, the solar cell 80 preferably includes a plurality of electrode pads 86 and a plurality of electrode pads 87, respectively. Thereby, it is possible to electrically and mechanically connect the cells 80a, 80b, 80c, and 80d and the wiring substrate 82 to each other in a reliable manner.

In addition, the plurality of electrode pads 86 are arranged along the outer periphery of the solar cell 80. Meanwhile, the plurality of electrode pads 87 are arranged along the inner periphery of the solar cell 80. By adopting such an arrangement, it is possible to ensure that there are connection points along the extending direction (circumferential direction) of the solar cell 80. Therefore, the solar cell 80 can be more reliably fixed, and the contact resistance between the solar cell 80 and the wiring substrate 82 can be sufficiently reduced.

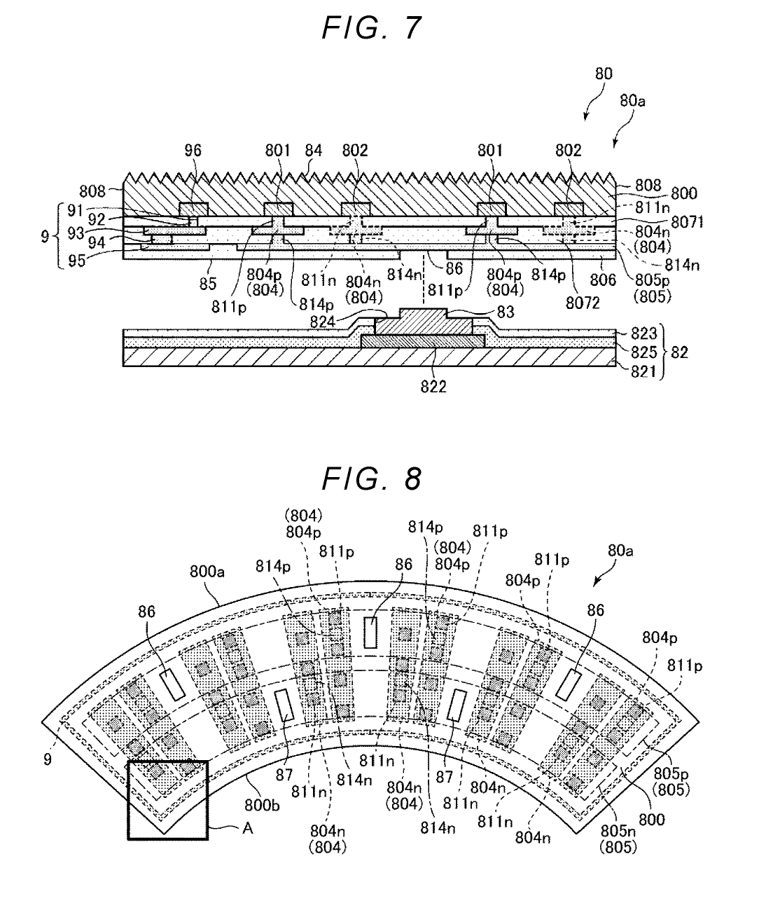

FIG. 7 is an exploded sectional view of the solar cell 80 shown in FIG. 5. In FIG. 7, an example of using a Si substrate 800 as a semiconductor substrate is illustrated. The solar cell 80 shown in FIG. 7 includes a cell 80a and a wiring substrate 82.

Among the solar cells, the cell 80a includes a Si substrate 800, a p+ impurity region 801 (the first conductivity type impurity region) and an n+ impurity region 802 (the second conductivity type impurity region) formed in the Si substrate 800, a finger electrode 804 which is electrically connected to the p+ impurity region 801 and the n+ impurity region 802, and a bus bar electrode 805 which is electrically connected to the finger electrode 804. For convenience of illustration, in FIG. 7, only the bus bar electrode 805 and the electrode pad 86 (positive electrode) connected to the p+ impurity region 801 are shown, and the bus bar electrode and the electrode pad (negative electrode) connected to the n+ impurity region 802 are not shown. In addition, in FIG. 7, the finger electrode 804 connected to the n+ impurity region 802 is indicated by a dashed line, and this means that the finger electrode 804 is not electrically connected to the bus bar electrode 805.

The p+ impurity region 801 and the n+ impurity region 802 serve as a power generating unit for generating electric power in the cell 80a based on photoelectric conversion.

As the Si substrate 800, a Si (100) substrate or the like is used, for example. It should be noted that the crystal plane of the Si substrate 800 is not particularly limited, and it may be a crystal plane other than the Si (100) plane.

In addition, the semiconductor substrate used in the invention may have characteristics of a p-type semiconductor, but the Si substrate 800 according to this embodiment has characteristics of an n-type semiconductor.

It is preferable that a concentration of impurity elements other than the main constituent elements of the Si substrate 800 (semiconductor substrate) is as low as possible, but more preferably, equal to or less than 1×10¹¹ atoms/cm², and still more preferably, equal to or less than 1×10¹⁰ atoms/cm². When the concentration of the impurity element is within the range described above, the influence of the impurity of the Si substrate 800 on the photoelectric conversion can be suppressed sufficiently small. Thereby, it is possible to realize the solar cell 80 capable of generating sufficient electric power while occupying a small area. Further, there is also an advantage that the photoelectric conversion efficiency is hardly lowered even with a low illuminance light such as indoor light.

It should be noted that the impurity element concentration of the Si substrate 800 can be measured by Inductively Coupled Plasma-Mass Spectrometry (ICP-MS), for example.

In addition, a portion of the bus bar electrode 805 connected to the p+ impurity region 801 is exposed to form the electrode pad 86 described above. Meanwhile, a portion of a bus bar electrode (not shown) connected to the n+ impurity region 802 is exposed to form the electrode pad 87 described above.

In addition, as shown in FIG. 7, the electrode pad 86 is electrically connected to the wiring substrate 82 through a conductive connection portion 83. Likewise, the electrode pad 87 is also electrically connected to the wiring substrate 82 through a conductive connection portion (not shown).

Examples of the conductive connection portion 83 include a conductive paste, a conductive sheet, a metal material, a solder, a brazing material, and the like.

A texture is formed on the light receiving surface 84 of the Si substrate 800. This texture means an uneven shape having any shape, for example. Specifically, it is configured by a plurality of pyramid-shaped projections formed on the light receiving surface 84, for example. By providing such a texture, it is possible to suppress the reflection of external light on the light receiving surface 84 and increase the amount of light incident on the Si substrate 800.

For example, when the Si substrate 800 is a substrate having a Si (100) plane as a main plane, a pyramid-shaped projection having a Si (111) plane as an inclined plane is suitably used as the texture.

In addition, the solar cell 80 has a passivation film (not shown) provided on the light receiving surface 84. This passivation film may serve as an anti-reflection film. Meanwhile, the solar cell 80 includes a passivation film 806 provided on the electrode plane 85.

In addition, the finger electrode 804 and the Si substrate 800 are insulated from each other through an interlayer insulating film 8071, and the bus bar electrode 805 and the finger electrode 804 are insulated from each other through an interlayer insulating film 8072 interposed therebetween.

Examples of a constituent material of the passivation film 806 and the interlayer insulating films 8071 and 8072 include silicon oxide, silicon nitride, silicon oxynitride, aluminum oxide, and the like. Among them, particularly silicon oxide or silicon oxynitride is preferably used as a constituent material of the interlayer insulating films 8071 and 8072, and the silicon oxide is more preferably used. Meanwhile, silicon nitride or silicon oxynitride is preferably used as the constituent material of the passivation film 806, and the silicon nitride is more preferably used.

Examples of a constituent material of the finger electrode 804 and the bus bar electrode 805 include a simple metal such as aluminum, titanium, copper, and the like, or an alloy thereof.

In addition, the cell 80a has the moisture-proof structure 9 located outside the power generating unit when the main surface of the Si substrate 800 is seen in a plan view. By providing such a moisture-proof structure 9, it is possible to suppress an ingress of moisture from an end surface 808 of the cell 80a, or particularly, from the end surfaces of the interlayer insulating films 8071 and 8072 toward the power generating unit. Therefore, such a cell 80a has a high moisture resistance without being increased in size. The moisture-proof structure 9 will be described below in detail.

The wiring substrate 82 includes an insulating substrate 821 and a conductive film 822 provided thereon.

While the length d (see FIG. 3) of the gap between the cells 80a, 80b, 80c, and 80d is not particularly limited, but it is preferably equal to or greater than 0.05 mm and equal to or less than 3 mm, and more preferably equal to or greater than 0.1 mm and equal to or less than 1 mm. By setting the length d of the gap within the range described above, when viewing the solar cell 80 from the light receiving surface 84 side, the end surface 808 shown in FIG. 7 becomes more invisible. It is also useful from the viewpoint of avoiding the problem of difficulty in assembling the solar cell 80 and easily coming into contact with the cells each other due to the fact that the length d of the gap is too short.

In addition, while the thickness of each cell 80a, 80b, 80c, and 80d is not particularly limited, it is preferably equal to or greater than 50 μm and equal to or less than 500 μm, and more preferably equal to or greater than 100 μm and equal to or less than 300 μm. Thereby, both of the photoelectric conversion efficiency and the mechanical characteristics of the solar cell 80 can be achieved. Further, it can also contribute to the thinning of the electronic timepiece 200.

The wiring substrate 82 is provided to overlap the four cells 80a, 80b, 80c, and 80d. Such a wiring substrate 82 includes an insulating substrate 821, a conductive film 822 provided thereon, and an insulating film 823 including an opening 824 in a portion overlapping with the conductive film 822.

It should be noted that “the wiring substrate 82 overlapping with the four cells 80a, 80b, 80c, and 80d” means a state in which the wiring substrate 82 overlaps with at least one cell when the wiring substrate 82 is seen in a plan view. In addition, in that case, it is not necessary to entirely overlap with the one cell, but it may overlap with at least a portion thereof.

In this embodiment, the wiring substrate 82 overlaps with the four cells 80a, 80b, 80c, and 80d.

Examples of an insulating substrate 821 include various resin substrates such as a polyimide substrate and a polyethylene terephthalate substrate.

Examples of a constituent material of the conductive film 822 include a copper or a copper alloy, an aluminum or an aluminum alloy, a silver or a silver alloy or the like.

Examples of a constituent material of the insulating film 823 include various resin materials such as a polyimide resin and a polyethylene terephthalate resin.

In addition, the insulating substrate 821 and the insulating film 823 adhere to each other through an adhesive layer 825.

Examples of a constituent material of the adhesive layer 825 include an epoxy type adhesive, a silicone type adhesive, an olefin type adhesive, an acrylic type adhesive and the like.

While the thickness of the wiring substrate 82 is not particularly limited, but it is preferably equal to or greater than 50 μm and equal to or less than 500 μm, and more preferably equal to or greater than 100 μm and equal to or less than 300 μm. An appropriate flexibility is imparted to the wiring substrate 82 by setting the thickness of the wiring substrate 82 within the range described above. Therefore, an appropriate deformability is imparted to the wiring substrate 82, and even when a stress is generated in the cell 80a, the concentration of the stress can be alleviated by the deformation of the wiring substrate 82. As a result, the occurrence of defects such as warping in the cells 80a, 80b, 80c, and 80d can be suppressed.

### Electrode and Electrode Pad (Connection Portion)

Hereinafter, each part will be described in more detail. FIG. 8 is a plan view showing the electrode plane 85 of the cell 80a shown in FIG. 6. In FIG. 8, the finger electrodes 804 and the bus bar electrodes 805 covered by the passivation film 806 described above are illustrated to be seen through.

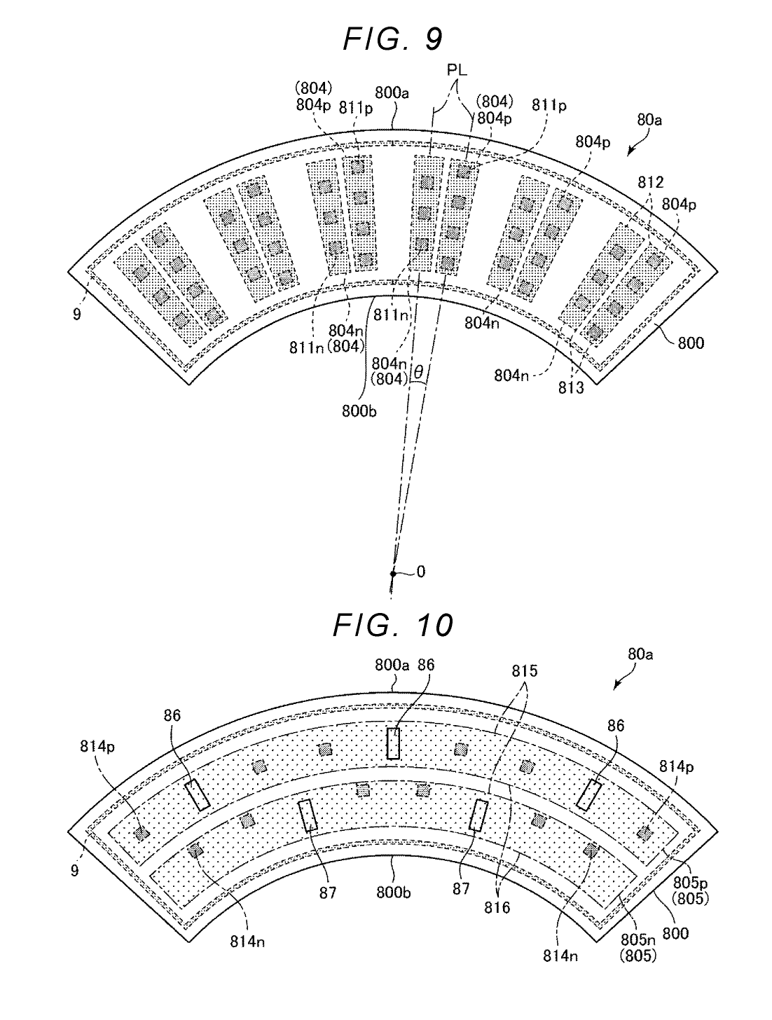

In addition, FIG. 9 is a view showing selectively the finger electrode 804 in the plan view shown in FIG. 8, and FIG. 10 is a view showing selectively bus bar electrode 805 and electrode pads 86 and 87 in the plan view shown in FIG. 8. Since the finger electrode 804 and the bus bar electrode 805 are different in hierarchy from each other, they are shown as separate layers in FIGS. 9 and 10.

In the following description, the cell 80a will be described as a representative example, but the explanation thereof is also applied to the rest cells 80b, 80c and 80d.

As shown in FIGS. 8 to 10, the cell 80a includes a Si substrate 800. The Si substrate 800 includes two circular arcs in the outline. Among them, the circular arc corresponding to the outer periphery of the annular shape shown in FIG. 5 is a substrate outer periphery 800a, and the circular arc corresponding to the inner periphery of the annular shape is a substrate inner periphery 800b.

In addition, the cell 80a shown in FIGS. 8 to 10 includes a p-type finger electrode 804p (the first electrode) provided to cover the p+ impurity region 801 shown in FIG. 7 formed in the Si substrate 800 (the first conductivity type impurity region) and a p+ contact 811p for electrically connecting the p+ impurity region 801 and the p-type finger electrode 804p.

In addition, the cell 80a shown in FIGS. 8 to 10 includes an n-type finger electrode 804n (the second electrode) provided to cover the n+ impurity region 802 shown in FIG. 7 formed in the Si substrate 800 (the second conductivity type impurity region) and an n+ contact 811n for electrically connecting the n+ impurity region 802 and the n-type finger electrode 804n.

Further, a plurality of p+ contacts 811p are provided for one p-type finger electrode 804p. Therefore, a plurality of p+ impurity regions 801 shown in FIG. 7 are also provided for one p-type finger electrode 804p accordingly. As a result, holes (carriers) generated by the light reception can be efficiently extracted.

Likewise, a plurality of n+ contacts 811n are provided for one n-type finger electrode 804n. Therefore, a plurality of n+ impurity regions 802 shown in FIG. 7 are also provided for one n-type finger electrode 804n accordingly. As a result, electrons (carriers) generated by the light reception can be efficiently extracted.

Therefore, the region including the p+ impurity region 801 and the n+ impurity region 802 in the Si substrate 800 serves as a power generating unit.

The constituent materials of the p+ contact 811p and the n+ contact 811n are appropriately selected from those similar to the constituent materials of the finger electrode 804 described above, for example.

It should be noted that the finger electrode 804 described above refers to both the p-type finger electrode 804p and the n-type finger electrode 804n.

In addition, in FIGS. 8 and 9, relatively dense dots are given to the p+ contact 811p and the n+ contact 811n, and relatively sparse dots are given to the finger electrode 804. Further, dots are also given to the moisture-proof structure 9 described below.

Further, in FIG. 8, a portion covered with the passivation film 806 is indicated by dashed lines or dotted lines, and a portion exposed from the passivation film 806 are indicated by solid lines.

As shown in FIG. 8, the p-type bus bar electrode 805p and the n-type bus bar electrode 805n are covered with the passivation film 806. As a result, these electrodes are protected from the external environment.

### Electrode Pad (Connection Portion)

Meanwhile, a via hole is provided in a portion of the passivation film 806, so that a portion of the p-type bus bar electrode 805p and the n-type bus bar electrode 805n is exposed. Among them, the exposed surface of the p-type bus bar electrode 805p is the electrode pad 86 (positive electrode) described above and the exposed surface of the n-type bus bar electrode 805n is the electrode pad 87 (negative electrode) described above.

In addition, as shown in FIG. 10, the cell 80a according to the present embodiment includes a plurality of electrode pads 86 and a plurality of electrode pads 87, respectively. The conductive connection portion 83 (see FIG. 7) is provided between the electrode pads 86 and 87 and the conductive film 822 of the wiring substrate 82, so that the cell 80a can be electrically and mechanically connected to the wiring substrate 82. Then, the electric power generated by the power generating unit described above can be transmitted from the electrode pads 86 and 87 to the wiring substrate 82.

In addition, as shown in FIGS. 8 and 10, the plurality of electrode pads 86 are arranged along the substrate outer periphery 800a. That is, the arrangement axis of the electrode pad 86 is substantially parallel to the substrate outer periphery 800a. Meanwhile, the plurality of electrode pads 87 are arranged along the substrate inner periphery 800b. That is, the arrangement axis of the electrode pad 87 is substantially parallel to the substrate inner periphery 800b. By adopting such an arrangement, a connection point with the wiring substrate 82 can be ensured along the extending direction of the cell 80a (circumferential direction of the circular arc included in the substrate outer periphery 800a). Therefore, it is possible to securely fix the cell 80a to the wiring substrate 82, and it is possible to sufficiently reduce the contact resistance between the cell 80a and the wiring substrate 82.

In addition, as described above, a plurality of electrode pads 86 and 87 are provided in the cell 80a according to the present embodiment, respectively. With such an arrangement, the conductive connection portion 83 bonded to this connection portion is also arranged in the same position. Therefore, the cell 80a is supported at multiple points on the wiring substrate 82 with the positions of the electrode pads 86 and 87 as support points. As a result, it is possible to further reduce the contact resistance and enhance the connection strength.

It should be noted that the arrangement of the electrode pads 86 and 87 is not limited to that shown in the drawings, and the positions of the rows of the electrode pads 86 and the positions of the rows of the electrode pads 87 may be interchanged, for example. That is, the connection portion of the positive electrode may be disposed on the substrate inner periphery 800b side, and the connection portion of the negative electrode may be disposed on the substrate outer periphery 800a side.

Meanwhile, the shortest distance between the electrode pads 86 and 87 and the outline of the Si substrate 800 is preferably equal to or greater than 0.05 mm and equal to or less than 1 mm, and more preferably, equal to or greater than 0.1 mm and equal to or less than 0.8 mm. The shortest distance is within the range described above, so that the electrode pads 86 and 87 are located inside the Si substrate 800, such that, even when solder or the like overflows from the electrode pads 86 and 87, the solder can be suppressed from reaching the end surface 808, for example. In addition, when supporting the electrode pads 86 and 87 through the conductive connection portion 83, the shortest distance is within the range described above, so that it is possible to support the cells 80a in a well-balanced manner. As a result, a highly reliable solar cell 80 can be realized.

In addition, the shapes of the electrode pads 86 and 87 are not particularly limited, and any shape maybe adopted. As an example, the shape of the electrode pads 86 and 87 shown in FIG. 10 is each a rectangle, but may be a round shape such as a perfect circle, an ellipse, an oval, or may be a polygonal shape such as a triangle, a hexagon, an octagon, or may be any other shape.

Further, it is preferable that the shapes are the same between the electrode pads 86, between the electrode pads 87, and between the electrode pads 86 and 87, but they may be different from each other.

In addition, it is preferable that the substrate outer periphery 800a and the substrate inner periphery 800b include circular arcs concentric with each other. That is, it is preferable that the substrate outer periphery 800a includes a relatively large circular arc, and the substrate inner periphery 800b includes a relatively small circular arc. With this configuration, the design of the finger electrode 804 and the bus bar electrode 805 is facilitated and the balance of the structure of the cell 80a is optimized. As a result, deformation such as warping in the cell 80a is less likely to occur.

It should be noted that part or all of the substrate outer periphery 800a and the substrate inner periphery 800b may be straight, may include curved lines other than circular arcs, or may include circular arcs that are not concentric with each other.

However, in the present embodiment, the outline of the Si substrate 800 includes a curved line. As a result, the cell 80a contributes to further enhance design of the electronic timepiece 200.

It should be noted that, in some cases, the curved line as used herein may be manufactured as a part of a polygon having a plurality of corners due to restrictions in manufacturing techniques, as it encompasses a part of such a polygon.

In addition, the substrate outer periphery 800a is longer than the substrate inner periphery 800b. Considering this, it is preferable that the number of the electrode pads 86 positioned on the substrate outer periphery 800a side is larger than the number of the electrode pads 87 positioned on the substrate inner periphery 800b side.

In the present embodiment, in a portion where the electrode pads 86 and 87 are provided, a p+ impurity region 801 (see FIG. 7), an n+ impurity region 802 (see FIG. 7), a p+ contact 811p and an n+ contact 811n are arranged so as not to overlap each other in a plan view (see FIG. 8).

That is, when the main surface of the Si substrate 800 is seen in a plan view, the electrode pad 86 is arranged at a misalignment with the p+ impurity region 801 and the n+ impurity region 802. In addition, by virtue of this, the electrode pad 86 is arranged at a misalignment with the p+ contact 811p and the n+ contact 811n.

Likewise, when the main surface of the Si substrate 800 is seen in a plan view, the electrode pad 87 is arranged at a misalignment with the p+ impurity region 801 and the n+ impurity region 802. In addition, by virtue of this, the electrode pad 87 is arranged at a misalignment with the p+ contact 811p and the n+ contact 811n.

With this configuration, for example, after the conductive connection portion 83 is bonded to the electrode pads 86 and 87, even when the bonded portion is damaged, it is possible to suppress damage to the p+ impurity region 801 and the n+ impurity region 802. Therefore, a more reliable cell 80a is obtained.

In addition, with the above arrangement, the shape of the electrode pads 86 and 87 such as flatness is not affected by the p+ contact 811p and the n+ contact 811n. As a result, the electrode pads 86 and 87 which have high flatness and are less likely to cause contact failure are obtained.

It should be noted that such an arrangement is not necessarily limiting, and for example, the electrode pads 86 and 87 may overlap with any one of the p+ impurity region 801, the n+ impurity region 802, the p+ contact 811p, and the n+ contact 811n in a plan view.

### Finger Electrode

As shown in FIG. 9, it is preferable that the finger electrode 804 extends in the extending direction of the perpendicular PL of the curved line included in the substrate outer periphery 800a. That is, the cell 80a preferably includes a Si substrate 800 having a substrate outer periphery 800a including a curved line and a substrate inner periphery 800b located inside the substrate outer periphery 800a and including a curved line, and a plurality of finger electrodes 804 provided on one surface of the Si substrate 800, and the finger electrodes 804 preferably extend in the perpendicular direction of the curved line included in the substrate outer periphery 800a. Accordingly, when the substrate outer periphery 800a is a circular arc, the finger electrode 804 extends along a straight line radially extending from the center O of the circular arc.

Meanwhile, in the cell 80a according to the present embodiment, the perpendicular line PL described above is also orthogonal to the substrate inner periphery 800b.

In addition, it is preferable that the perpendicular line PL described above passes through the center O of the circular arc of the substrate outer periphery 800a. That is, it is preferable that the circular arc is a part of a perfect circle or a shape close to the perfect circle.

With this configuration, the design of the finger electrode 804 is facilitated and the balance of the structure of the cell 80a is optimized. As a result, deformation such as warping in the cell 80a is less likely to occur.

In addition, a plurality of finger electrodes 804 are provided in the cell 80a. Therefore, these finger electrodes 804 are arranged (aligned) along the substrate outer periphery 800a. In other words, it can be considered that the arrangement axis is substantially parallel to the substrate outer periphery 800a. With this arrangement, it is possible to equalize the shape and area of each finger electrode 804, and it enables the structure of the cell 80a to be formed uniformly. As a result, deformation such as warping in the cell 80a is less likely to occur. In addition, the finger electrodes 804 can be spread on the Si substrate 800 as closely as possible, and without a gap if possible. Accordingly, the finger electrodes 804 also serve as a reflecting film for reflecting the light incident from the light receiving surface 84 on the electrode plane 85 side of the cell 80a. That is, since the finger electrodes 804 are spread without gaps, the light which is impinged on the light receiving surface 84 and transmitted through the Si substrate 800 can be reflected with a higher probability at the finger electrodes 804. As a result, the amount of light contributing to the photoelectric conversion can be increased, and the photoelectric conversion efficiency can be improved.

Further, it is preferable that at least the adjacent finger electrodes 804 to each other have the same shape and occupy the same area. As a result, the uniformity of the structure of the cell 80a can be achieved.

It should be noted that the same shape, the same area and the parallel state are concepts that include tolerance to an error occurring at the time of manufacture.

In addition, when the finger electrodes 804 are arranged along the substrate outer periphery 800a, it is preferable that the p-type finger electrodes 804p and the n-type finger electrodes 804n are alternately arranged side by side, but not limited to such an arrangement pattern, and accordingly, part or all of the arrangement patterns may be different from each other.

In addition, the outline of the finger electrode 804 may have any shape, but in FIG. 9, the outline of the finger electrode 804 includes a finger electrode outer periphery 812 facing the substrate outer periphery 800a and a finger electrode inner periphery 813 facing the substrate inner periphery 800b. The length of the finger electrode outer periphery 812 is longer than the length of the finger electrode inner periphery 813. That is, the width of the finger electrode 804 shown in FIG. 9 gradually increases from the inner periphery 813 of the finger electrode toward the outer periphery 812 of the finger electrode when the length of the substrate outer periphery 800a in the extending direction is “width”.

According to the finger electrode 804 having such an outline shape, it is possible to spread the finger electrodes 804 on the Si substrate 800 as closely as possible, and without a gap if possible, while keeping a constant gap between the finger electrodes 804. Therefore, it is possible to further enhance the function of the finger electrode 804 as a reflecting film while ensuring the insulation property between the finger electrodes 804.

In addition, when it is assumed that the two perpendicular lines PL shown in FIG. 9 pass through the centers of the widths of the two adjacent finger electrodes 804 to each other, each perpendicular line PL passes through the center O of the circular arc of the substrate outer periphery 800a. Therefore, the angle θ formed by the two perpendicular lines PL corresponds to a pitch between the adjacent finger electrodes 804 to each other. This angle θ is appropriately set in accordance with the carrier mobility and the like in the Si substrate 800, and for example, it is preferably equal to or greater than 0.05° and equal to or less than 1°, and more preferably, equal to or greater than 0.1° and equal to or less than 0.5°. As a result, the pitch between the contacts provided corresponding to each finger electrode 804 and the pitch between the impurity regions are optimized, so that the extraction efficiency of carriers generated by receiving the light is enhanced. As a result, a cell 80a having particularly high photoelectric conversion efficiency can be obtained.

In addition, the width of the finger electrode 804 is preferably equal to or greater than 5 μm and equal to or less than 100 μm, and more preferably, equal to or greater than 10 μm and equal to or less than 50 μm, from the same viewpoint as described above.

Meanwhile, the interval between the finger electrodes 804 is preferably equal to or greater than 1 μm and equal to or less than 50 μm, and more preferably, equal to or greater than 3 μm and equal to or less than 30 μm. Thus, it is possible to sufficiently increase the area occupied by the finger electrodes 804 while ensuring the insulation between the finger electrodes 804.

### Bus Bar Electrode

Meanwhile, as shown in FIGS. 8 and 10, the cell 80a includes a p-type bus bar electrode 805p and an n-type bus bar electrode 805n provided to bridge the finger electrodes 804 and to cover the finger electrodes 804, respectively. The p-type bus bar electrode 805p is electrically connected to the plurality of p-type finger electrodes 804p through the p-type via wiring 814p, and the n-type bus bar electrode 805n is electrically connected to the plurality of n-type finger electrode 804n through the n-type via wiring 814n.

In addition, a plurality of p-type via wirings 814p are provided for one p-type bus bar electrode 805p. Likewise, a plurality of n-type via wirings 814n are also provided for one n-type bus bar electrode 805n.

The constituent materials of the p-type via wirings 814p and the n-type via wirings 814n are appropriately selected from those similar to the constituent materials of the bus bar electrode 805 described above, for example.

It should be noted that the bus bar electrode 805 described above refers to both the p-type bus bar electrode 805p and the n-type bus bar electrode 805n.

In addition, in FIG. 10, relatively dense dots are given to the p-type via wiring 814p and the n-type via wiring 814n, and relatively sparse dots are given to the bus bar electrode 805. Further, dots are also given to the moisture-proof structure 9 described below.

Here, as shown in FIGS. 8 and 10, the extending direction of the bus bar electrode 805 intersects the extending direction of the finger electrode 804. That is, as described above, the finger electrode 804 extends in the perpendicular direction of the substrate outer periphery 800a, while the bus bar electrode 805 extends in the direction parallel to the substrate outer periphery 800a. Therefore, when the main surface of the Si substrate 800 is seen in a plan view as shown in FIG. 8, the finger electrode 804 and the bus bar electrode 805 are substantially perpendicular to each other. As a result, since the bus bar electrode 805 is disposed to bridge the plurality of finger electrodes 804, the bus bar electrode 805 becomes an effective (less wastefully shaped) current collector when the p-type via wiring 814p or the n-type via wiring 814n is disposed at the intersection of both.

The “parallel direction” refers to a state in which the bus bar electrode 805 and the substrate outer periphery 800a are displaced while maintaining a substantially constant distance. Further, by “maintaining a constant distance”, it means that a variation width of the spacing distance between the two sides along the entire length of the bus bar electrode 805 is equal to or less than 100% of the maximum value of the spacing distance (preferably equal to or less than 10% of the average value of the spacing distance).

In addition, the crossing angle between the finger electrode 804 and the bus bar electrode 805 is not limited to 90°, and the angle of the acute angle side may be about equal to or greater than 30° and less than 90°. In addition, the bus bar electrode 805 is not necessarily required to be parallel to the substrate outer periphery 800a, and may extend linearly.

As described above, the bus bar electrode 805 according to the present embodiment overlaps with the finger electrode 804 in the thickness direction of the Si substrate 800. Accordingly, it is not necessary to ensure that a space is provided for disposing the bus bar electrode 805, and accordingly, it is possible to ensure that a wider space is provided for arranging the finger electrode 804, the p+ impurity region 801 and the n+ impurity region 802 in the Si substrate 800. As a result, an increased number of carriers can be extracted, and the functions of the finger electrode 804 and the bus bar electrode 805 as a reflecting film are enhanced, which results in further enhanced photoelectric conversion efficiency.

It should be noted that the bus bar electrode 805 is insulated from the finger electrode 804 by the interlayer insulating film 8072 shown in FIG. 7, while the bus bar electrode 805 is electrically connected to the finger electrode 804 through the p-type via wiring 814p and the n-type via wiring 814n passing through a portion of the interlayer insulating film 8072.

At this time, in the plan view of the main surface of the Si substrate 800, the position of the p-type via wiring 814p may be overlapped with the position of the p+ contact 811p, but it is preferable that the position of the p-type via wiring 814p is misaligned with the position of the p+ contact 811p. Likewise, in the plan view of the main surface of the Si substrate 800, the position of the n-type via wiring 814n may be overlapped with the position of the n+ contact 811n, but it is preferable that the position of the n-type via wiring 814n is misaligned with the position of the n+ contact 811n. As a result, the flatness of the underlying layer of the p-type via wiring 814p and the n-type via wiring 814n is increased, so that a deviation of the formation position and manufacturing defects and the like are less likely to occur. Therefore, it is possible to suppress a decrease in the manufacturing yield of the cell 80a.

Preferably, the position of the p-type via wiring 814p is provided between the p+ contacts 811p, and the position of the n-type via wiring 814n is provided between the n+ contacts 811n.

In addition, the outline of the bus bar electrode 805 may have any shape, but in FIG. 10, the outline of the bus bar electrode 805 has a shape having a bus bar electrode outer periphery 815 facing the substrate outer periphery 800a and a bus bar electrode inner periphery 816 facing the substrate inner periphery 800b. Then, the length of the bus bar electrode outer periphery 815 is greater than the length of the bus bar electrode inner periphery 816. That is, the width of the bus bar electrode 805 shown in FIG. 10 gradually increases from the bus bar electrode inner periphery 816 toward the bus bar electrode outer periphery 815 when the length of the substrate outer periphery 800a in the extending direction is “width”.

According to the bus bar electrode 805 having such an outline shape, a shape similar to that of the Si substrate 800, that is, a shape obtained by cutting out a portion of a circular shape is obtained. Therefore, it is easy to intersect the bus bar electrodes 805 with the plurality of finger electrodes 804 spread all over the Si substrate 800, and it is easy to arrange a plurality of the p-type bus bar electrodes 805p and a plurality of the n-type bus bar electrodes 805n.

In addition, as described above, regarding the bus bar electrode 805, the finger electrode 804 and the bus bar electrode 805 are substantially perpendicular to each other. Therefore, it is possible to obtain the effect that the p-type via wiring 814p and the n-type via wiring 814n are easily arranged at the intersection of the two.

When the bus bar electrode outer periphery 815 faces the substrate outer periphery 800a, it means that both are displaced while maintaining a substantially constant distance. Further, “by maintaining a constant distance” means that a variation width of a spacing distance between the two sides along the entire length of the bus bar electrode outer periphery 815 is equal to or less than 100% of the maximum value of the spacing distance (preferably equal to or less than 10% of the average value of the spacing distance).

Likewise, when the bus bar electrode inner periphery 816 faces the substrate inner periphery 800b, it means that both are displaced while maintaining a substantially constant distance. Further, “by maintaining a constant distance” means that a variation width of a spacing distance between the two sides along the entire length of the bus bar electrode inner periphery 816 is equal to or less than 100% of the maximum value of the spacing distance (preferably equal to or less than 10% of the average value of the spacing distance).

### Moisture-Proof Structure

The cell 80a is located outside the power generating unit when the main surface of the Si substrate 800 is seen in a plan view, and includes a groove 91 provided in the interlayer insulating film 8071 (insulating layer), and a first plug layer 92 provided in the groove 91 and having a lower moisture permeability than the interlayer insulating film 8071. In addition, the cell 80a according to the present embodiment includes a first another layer 93 which is continuous from the first plug layer 92 and provided in the same layer as the finger electrode 804. A first barrier layer is configured by the first plug layer 92 and the first another layer 93.

Further, the cell 80a according to the present embodiment includes a second plug layer 94 which is continuous from the first another layer 93 and provided in the same layer as the p-type via wiring 814p and the n-type via wiring 814n. In addition, the cell 80a according to the present embodiment includes a second another layer 95 which is continuous from the second plug layer 94 and provided in the same layer as the bus bar electrode 805. The second barrier layer is configured by the second plug layer 94 and the second another layer 95.

In addition, the second another layer 95 is covered with the passivation film 806 together with the bus bar electrode 805.

Therefore, the moisture-proof structure 9 according to the present embodiment is a laminate including the groove 91, the first plug layer 92, the first another layer 93, the second plug layer 94, and the second another layer 95.

That is, the cell 80a according to the present embodiment includes the Si substrate 800 (semiconductor substrate), the p+ impurity region 801 (the first conductivity type impurity region) and the n+ impurity region 802 (the second conductivity type impurity region) formed in the Si substrate 800, an interlayer insulating film 8071 (insulating layer) provided to overlap with the p+ impurity region 801 and the n+ impurity region 802 when the main surface of the Si substrate 800 is seen in a plan view, a p-type finger electrode 804p (the first electrode) electrically connected to the p+ impurity region 801 and an n-type finger electrode 804n (the second electrode) electrically connected to the n+ impurity region 802.

Further, the cell 80a according to the present embodiment includes at least a groove 91 which is located outside the power generating unit (the p+ impurity region 801, the n+ impurity region 802, and the finger electrode 804 electrically connected thereto) when the main surface of the Si substrate 800 is seen in a plan view, and provided in the interlayer insulating film 8071, and a first barrier layer which is provided in the groove 91 and has lower moisture permeability than the interlayer insulating film 8071.

According to such a cell 80a, moisture can be suppressed from penetrating toward the power generating unit from the end surface 808, particularly, from the end surface of the interlayer insulating film 8071. That is, the moisture-proof structure 9 serves as a partition wall that blocks the ingress path of moisture. In addition, the moisture-proof structure 9 may be formed in a small space outside the power generating unit with the same thickness as the thickness of the power generating unit. Therefore, with such a cell 80a, moisture resistance can be enhanced without increasing the size of the cell 80a. In addition, it is possible to realize a small cell 80a having high moisture resistance.

When the moisture resistance is enhanced as described above, deterioration of the power generating unit and corrosion of a part including a metal such as a contact and an electrode due to moisture is suppressed. As a result, it is possible to realize a highly reliable solar cell 80 even when it is mounted on an electronic device such as an electronic timepiece 200 that is often used outdoors.

In particular, since the first plug layer 92 is provided in the groove 91 formed in the interlayer insulating film 8071, the first plug layer 92 blocks the ingress path of moisture in the interlayer insulating film 8071 with a high probability. Therefore, ingress of moisture from the external environment can be suppressed by forming the grooves 91 on the outside of the power generating unit.

In addition, in this embodiment, as shown in FIGS. 8 to 10, when the main surface of the Si substrate 800 is seen in a plan view, the moisture-proof structure 9 is arranged to continuously surround the power generating unit. Therefore, in the cell 80a according to the present embodiment, it is possible to more securely block the ingress path of moisture in the interlayer insulating film 8071. As a result, the moisture resistance of the cell 80a can be further enhanced.

The moisture-proof structure 9 is preferably provided along a periphery of the Si substrate 800. As a result, a sufficient space for providing the power generating unit is ensured inside the moisture-proof structure 9. As a result, in the cell 80a, both the moisture resistance and the photoelectric conversion amount can be achieved.

In addition, while the groove 91 is preferably as deep as possible with respect to the thickness of the interlayer insulating film 8071, it is particularly preferable that the groove 91 penetrates the interlayer insulating film 8071 in the thickness direction. As a result, the ingress path of moisture is blocked particularly reliably. When the groove 91 does not penetrate, the depth of the groove 91 is preferably equal to or greater than 70% of the thickness of the interlayer insulating film 8071, and more preferably equal to or greater than 90% of the thickness of the interlayer insulating film 8071 from the viewpoint of sufficiently reducing the probability of ingress of moisture.

Meanwhile, when the groove 91 penetrates the interlayer insulating film 8071, it is possible to electrically connect the first plug layer 92 provided in the groove 91 and the Si substrate 800. Therefore, the potential between the first plug layer 92 and the Si substrate 800 may be close to each other.

In addition, the cell 80a according to the present embodiment is provided to overlap with the moisture-proof structure 9 and includes an n-type high-concentration doping region 96 formed in the Si substrate 800. The n-type high-concentration doping region 96 is formed in the same manner as the n+ impurity region 802 described above, for example, and is a region doped with an n-type impurity at a high concentration.

In this embodiment, the n-type high-concentration doping region 96 is formed at a position facing the groove 91. That is, when the main surface of the Si substrate 800 is seen in a plan view, the n-type high-concentration doping region 96 and the groove 91 overlap with each other. As a result, the first plug layer 92 provided in the groove 91 is in contact with the n-type high-concentration doping region 96 and electrically connected to the Si substrate 800 with a low contact resistance. As a result, the first plug layer 92 and the Si substrate 800 are substantially equipotential through the n-type high-concentration doping region 96. That is, the n-type high-concentration doping region 96 reduces the contact resistance between the first plug layer 92 and the Si substrate 800. Therefore, a potential difference is less likely to occur between the first plug layer 92 and the Si substrate 800, which can suppress the occurrence of corrosion (electric field corrosion) caused by the potential difference.

In addition, likewise, with respect to the first another layer 93, the second plug layer 94, and the second another layer 95 connected to the first plug layer 92, the occurrence of corrosion can be suppressed. That is, in the present embodiment, the first another layer 93 and the second plug layer 94 are provided in the groove penetrating the interlayer insulating film 8072. Thus, it is possible to block the ingress path of moisture in the interlayer insulating film 8072. In addition, the lower surfaces of the second plug layer 94 and the interlayer insulating film 8072 in FIG. 7 are covered with the second another layer 95 and the passivation film 806. Therefore, it is also possible to suppress the ingress of moisture from the lower surface of the interlayer insulating film 8072 toward the power generating unit.

It should be noted that the n-type high-concentration doping region 96 is appropriately changed according to the type of the Si substrate 800. For example, when the Si substrate 800 has characteristics of a p-type semiconductor, a p-type high-concentration doping region may be provided in place of the n-type high-concentration doping region 96. Thereby, as described above, a potential difference is less likely to occur between the first plug layer 92 and the Si substrate 800, and therefore, the occurrence of corrosion can be suppressed.

The invention is not limited to the configuration described above. For example, the first plug layer 92, the first another layer 93, the second plug layer 94, and the second another layer 95 may not be equipotential with the Si substrate 800 when they have a sufficient width or thickness, or the like. That is, if the function of blocking the ingress path of moisture is not damaged even with the presence of some corrosion, the portion facing the groove 91 may be a p-type high-concentration doping region (a region formed in the same manner as the p+ impurity region 801, and doped with a p-type impurity at a high concentration) instead of the n-type high-concentration doping region 96 described above. In this case, the moisture-proof structure 9 and the p-type bus bar electrode 805p are electrically connected to each other, so that the moisture-proof structure 9 can be utilized also for photoelectric conversion and the photoelectric conversion efficiency of the cell 80a can be further enhanced.

In addition, the width of the first plug layer 92, that is, the length of the first plug layer 92 in the left and right direction in FIG. 7 may be as long as possible from the viewpoint of the moisture-proof function, and, for example, the length may be longer than the width of the n-type high-concentration doping region 96, although it is preferable that the length is shorter. Specifically, it is preferably equal to or greater than 0.05 μm and equal to or less than 30 μm, and more preferably equal to or greater than 0.1 μm and equal to or less than 10 μm. As a result, a sufficient water vapor blocking property is ensured in the first plug layer 92, so that it is possible to reliably block the ingress path of moisture without causing a significant enlargement of the cell 80a. It is preferable that the width of the groove 91 is appropriately set to be in the same range as the width of the first plug layer 92.

In addition, while the thickness of the first another layer 93, that is, the length of the first another layer 93 shown in FIG. 7 in the vertical direction may be as long as possible from the viewpoint of the moisture-proof function, it is preferably equal to or greater than 0.05 μm and equal to or less than 30 μm, and more preferably equal to or greater than 0.1 μm and equal to or less than 10 μm. As a result, a sufficient water vapor blocking property is ensured in the first another layer 93, so that it is possible to reliably block the ingress path of moisture without causing a significant thickness of the cell 80a.

Further, while the width of the second plug layer 94, that is, the length of the second plug layer 94 in FIG. 7 in the left and right direction may be as long as possible from the viewpoint of the moisture-proof function, it is preferably equal to or greater than 0.1 μm and equal to or less than 30 μm, and more preferably equal to or greater than 1 μm and equal to or less than 10 μm. As a result, a sufficient water vapor blocking property is ensured in the second plug layer 94, so that it is possible to reliably block the ingress path of moisture without causing a significant enlargement of the cell 80a.

In addition, the width of the first another layer 93, that is, the length of the first plug layer 92 in FIG. 7 in the left and right direction is preferably equal to or greater than 1.0 times and equal to or less than 100 times the width of the first plug layer 92 and equal to or greater than 1.5 times and equal to or less than 100 times the width of the second plug layer 94, and is more preferably equal to or greater than 3 times and equal to or less than 70 times the width of the first plug layer 92 and equal to or greater than 3 times and equal to or less than 70 times the width of the second plug layer 94. Specifically, it is preferably equal to or greater than 3 μm and equal to or less than 300 μm, and more preferably equal to or greater than 5 μm and equal to or less than 100 μm. As a result, when shifting the first plug layer 92 and the second plug layer 94 from each other, it is possible to ensure a sufficient offset while avoiding considerably increasing the size of the cell 80a.

In addition, while the depth of the groove 91, that is, the length of the groove 91 shown in FIG. 7 in the vertical direction is appropriately set according to the thickness of the interlayer insulating film 8071, it is preferable that the depth of the groove 91 is equal to or greater than 0.05 μm and equal to or less than 10 μm, and more preferably, equal to or greater than 0.1 μm and equal to or less than 5 μm. As a result, it is possible to ensure sufficient insulation property of the interlayer insulating film 8071 and to prevent degradation of moisture permeability due to excessive thickness.

In addition, in the plan view of the main surface of the Si substrate 800, the position of the second plug layer 94 may be overlapped with the position of the first plug layer 92, but it is preferable that the position of the second plug layer 94 is misaligned with the position of the first plug layer 92. As a result, when depositing the second plug layer 94, the underlying layer is less susceptible to the influence of the first plug layer 92, so that the flatness of the underlying layer is enhanced. Therefore, deviation in formation position of the second plug layer 94, manufacturing defects and the like are less likely to occur. As a result, deterioration of the moisture-proof function and reduction of the manufacturing yield of the cell 80a can be suppressed.

From this viewpoint, it is preferable that the width of the first another layer 93 is set to be wider than the widths of the first plug layer 92 and the second plug layer 94. Thereby, when shifting the first plug layer 92 and the second plug layer 94 from each other, a sufficient offset can be ensured, so that the ease of manufacturing can be enhanced.

In addition, in the present embodiment, the moisture-proof structure 9 is disposed to continuously surround the power generating unit as described above, and more specifically, when the main surface of the Si substrate 800 is seen in a plan view, an n-type high-concentration doping region 96 is provided to continuously surround the power generating unit provided with the p+ impurity region 801 and the n+ impurity region 802 and the like. With this configuration, the first plug layer 92 and the Si substrate 800 can be substantially equipotential in the entire moisture-proof structure 9. As a result, the moisture resistance of the cell 80a can be further enhanced.

In addition, while the first plug layer 92, the first another layer 93, the second plug layer 94, and the second another layer 95 may also include a portion where the moisture-proof structure 9 is partly discontinued, preferably, the moisture-proof structure 9 is disposed to continuously surround the power generating unit. As a result, the ingress path of moisture is blocked more reliably.

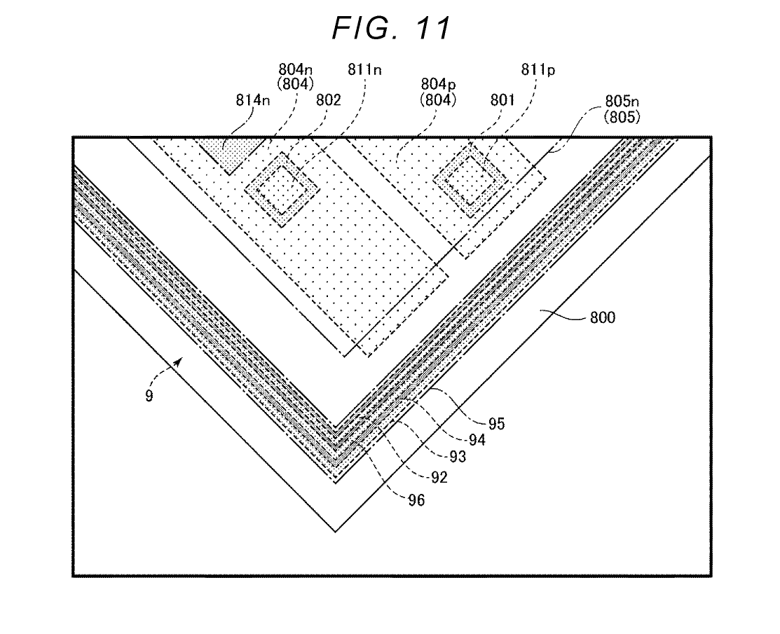

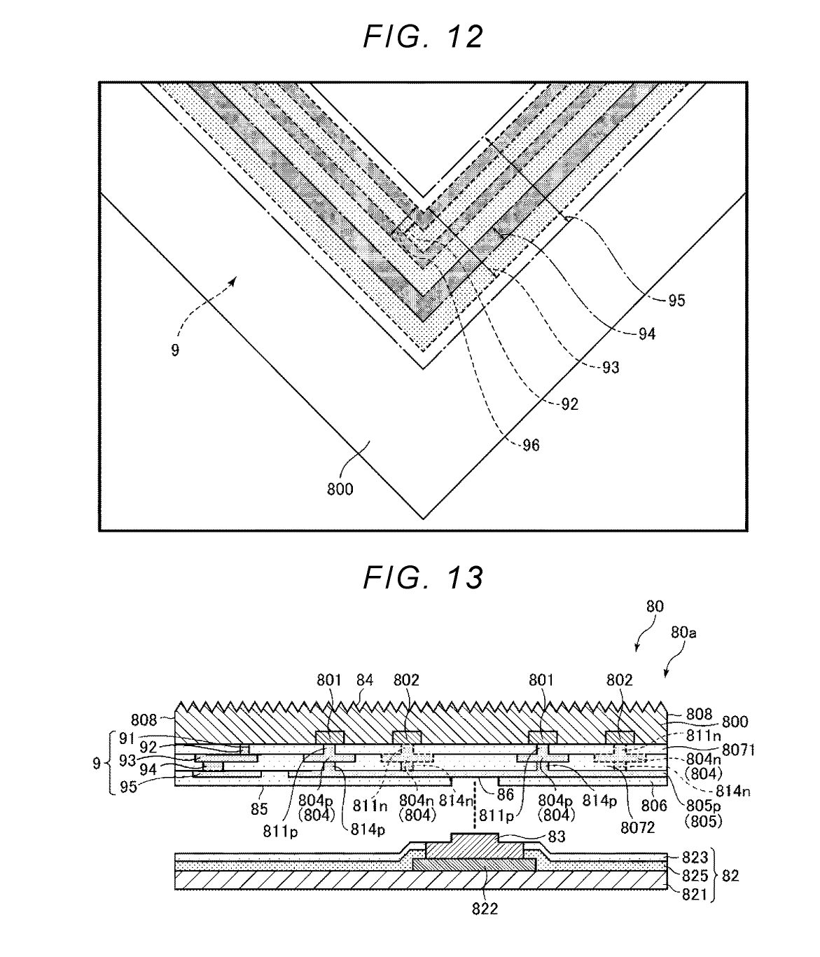

FIG. 11 is an enlarged view of the portion A shown in FIG. 8. In addition, FIG. 12 is a partially enlarged view showing a further enlarged view of FIG. 11. FIGS. 11 and 12 show the moisture-proof structure 9 when the main surface of the Si substrate 800 is viewed in a plan view, in which the multilayered structure is shown in perspective.

As shown in FIG. 11, the n-type high-concentration doping region 96, the first plug layer 92, the first another layer 93, the second plug layer 94, and the second another layer 95 extend in strips along a periphery of the Si substrate 800. Then, the n-type high-concentration doping region 96, the first plug layer 92, the first another layer 93, the second plug layer 94, and the second another layer 95 are laminated in this order on the Si substrate 800 side. As a result, in the moisture-proof structure 9, four layers are laminated on the Si substrate 800 to form a continuous partition wall that blocks the ingress path of moisture.

While the first plug layer 92, the first another layer 93, the second plug layer 94, and the second another layer 95 may be made of any material as long as the moisture permeability is lower than both of the interlayer insulating films 8071 and 8072, it may contain, for example, an inorganic material such as a metal material, a silicon-based material, a ceramic material, a glass material, an organic material such as a resin, a composite material thereof, or the like.

Among them, examples of the metal material include a simple metal such as aluminum, titanium, chromium, iron, copper, nickel, silver, gold, platinum, tungsten, an alloy containing these, and the like. In addition, the method of depositing each layer with a metal material is not particularly limited, but includes chemical vapor deposition (CVD), a gas phase film depositing method such as sputtering, plating, or the like, for example.

In addition, examples of the silicon-based material include silicon nitride, silicon oxynitride, silicon carbide, and the like.

In addition, examples of the ceramic material include aluminum oxide, zirconium oxide, titanium oxide, magnesium oxide, and the like.

Among them, the first plug layer 92, the first another layer 93, the second plug layer 94, and the second another layer 95 preferably include a metal material or silicon nitride, respectively. These materials are often used as a constituent material of various electrodes such as the finger electrode 804 and the passivation film 806 described above. Therefore, since these portions and the barrier layer can be formed at the same time, the manufacturing cost can be reduced. In addition, since the metal material or silicon nitride has a particularly low moisture permeability, it is possible to realize the cell 80a that maintains high moisture resistance over a long period of time.

In particular, the p-type finger electrode 804p (the first electrode), the n-type finger electrode 804n (the second electrode), and the first barrier layer (the first plug layer 92 and the first another layer 93) preferably include the same material as each other. Thus, since these portions can be formed at the same time, there is no need to separately provide steps of forming the first plug layer 92 and the first another layer 93, and the manufacturing cost can be particularly reduced.

Although the constituent materials of the first plug layer 92, the first another layer 93, the second plug layer 94 and the second another layer 95 may be different from each other, the constituent materials are preferably the same as each other. As a result, in particular, the manufacturing efficiency is enhanced, and the occurrence of troubles caused by the difference in thermal expansion coefficient can be suppressed.

In addition, the moisture permeability of the first plug layer 92 and the first another layer 93 can be quantified using water vapor permeability.

As described above, since the moisture permeability of the first plug layer 92 is preferably lower than the moisture permeability in the interlayer insulating films 8071 and 8072, from such a viewpoint, the water vapor permeability in the first plug layer 92 is preferably lower than the water vapor permeability of the interlayer insulating film 8071 and 8072.

The water vapor permeability is an amount of water vapor passing through a test sample having a unit area in a unit time under the condition that includes a predetermined temperature and humidity.

While the water vapor permeability of the first plug layer 92 may be as small as possible, as an example, a polyethylene terephthalate film having a thickness of 25 μm is used as a support film, and when using a test piece obtained by depositing the constituent material of the first plug layer 92 on the surface thereof to a thickness of 10 μm, it is preferably set to equal to or less than 25 g/m²-day, and more preferably the material content of equal to or less than 5 g/m²-day is used as a constituent material of the first plug layer 92. According to the first plug layer 92 that includes such a material having the water vapor permeability, it is possible to more securely block the ingress path of moisture in the interlayer insulating film 8071.

The water vapor permeability is measured by a moisture vapor permeability measuring device (PERMATRAN) manufactured by MOCON, for example, in conformity with the standards of JIS K 7129-7: 2016 and the like. In addition, measurement conditions include a temperature of 40° C. and a relative humidity of 90%, for example.

Meanwhile, the moisture permeability of the first another layer 93, the second plug layer 94 and the second another layer 95 may also be quantified using water vapor permeability. Therefore, the water vapor permeability of the first another layer 93, the second plug layer 94, and the second another layer 95 is preferably lower than the water vapor permeability of the interlayer insulating films 8071 and 8072, respectively.

In addition, the passivation film 806 preferably has a lower moisture permeability (water vapor permeability) than that of the interlayer insulating films 8071 and 8072. With this configuration, it is possible to more reliably suppress the ingress of moisture from the lower surface of the interlayer insulating film 8072 toward the power generating unit.

While the cell 80a is described above as a representative example, the solar cell 80 (photoelectric conversion module) includes such a cell 80a (photoelectric conversion element), a wiring substrate 82 provided to overlap with the cell 80a, and a conductive connection portion 83 for electrically connecting the electrode pads 86 and 87 of the cell 80a and the conductive film 822 of the wiring substrate 82. Therefore, the solar cell 80 has high photoelectric conversion efficiency and high mechanical strength of connection with the wiring substrate 82 which is an external wiring, which results in high reliability.

### Wiring Substrate

In addition, at least a portion of the electrode plane 85 of the cell 80a is covered by the wiring substrate 82, such that the electrode plane 85 is protected. Accordingly, it suppresses foreign matter adhering to the electrode plane 85 or application of an external force. As a result, the reliability of the electrode plane 85 can be ensured.

In other words, when the light receiving surface 84 is seen in a plan view, it is preferable that the conductive connection portion 83 is concealed behind the cell 80a (overlapping with the cell 80a). As a result, it is possible to enhance the aesthetic appearance of the solar cell 80 owing to the fact that the conductive connection portion 83 is not visually recognized in addition to the effect of ensuring the reliability described above. Therefore, it is possible to realize the electronic timepiece 200 having enhanced design.

In addition, the conductive connection portion 83 connects the cell 80a and the wiring substrate 82 not only electrically but also mechanically. Accordingly, it is possible to alleviate the concentration of stress in the cell 80a described above by optimizing the mechanical characteristics of the conductive connection portion 83. A conductive adhesive including a resin material is preferably used as the conductive connection portion 83.

Examples of a resin material included in the conductive adhesive include an epoxy resin, a urethane resin, a silicone resin, an acrylic resin, and the like, and one or two or more kinds of them are used as a mixture.

In addition, the electronic timepiece 200 (electronic device) includes the solar cell 80 including the four cells 80a, 80b, 80c, and 80d (photoelectric conversion elements). Therefore, the electronic timepiece 200 with high reliability can be obtained.

### Second Embodiment

Next, the solar cell 80 to which the second embodiment of the photoelectric conversion module according to the invention is applied will be described in detail. FIG. 13 is a cross-sectional view showing a photoelectric conversion module according to the second embodiment.

Hereinafter, the second embodiment will be described, but in the following description, differences from the first embodiment will be mainly described, and matters similar to the first embodiment will not be repeated. In FIG. 13, the same reference numerals are given to the same configurations as those of the first embodiment described above.

The solar cell 80 according to the second embodiment is the same as the solar cell 80 according to the first embodiment except that the n-type high-concentration doping region 96 is omitted.

That is, in the solar cell 80 shown in FIG. 13, the first plug layer 92 is in contact with the Si substrate 800 without having the n-type high-concentration doping region 96 therebetween. Accordingly, in the present embodiment, the first plug layer 92 is in an electrically floating state. Accordingly, while the first plug layer 92 and the Si substrate 800 are not substantially equipotential as described above, the function of blocking the ingress path of moisture is the same as in the first embodiment. Therefore, while the effect of suppressing the corrosion of the first plug layer 92 and the like is reduced, the moisture-proof function is maintained, and accordingly, in this embodiment, the cell 80a having high moisture resistance can still be obtained. It should be noted that the present embodiment has the same effects as those of the first embodiment other than described above.

### Third Embodiment

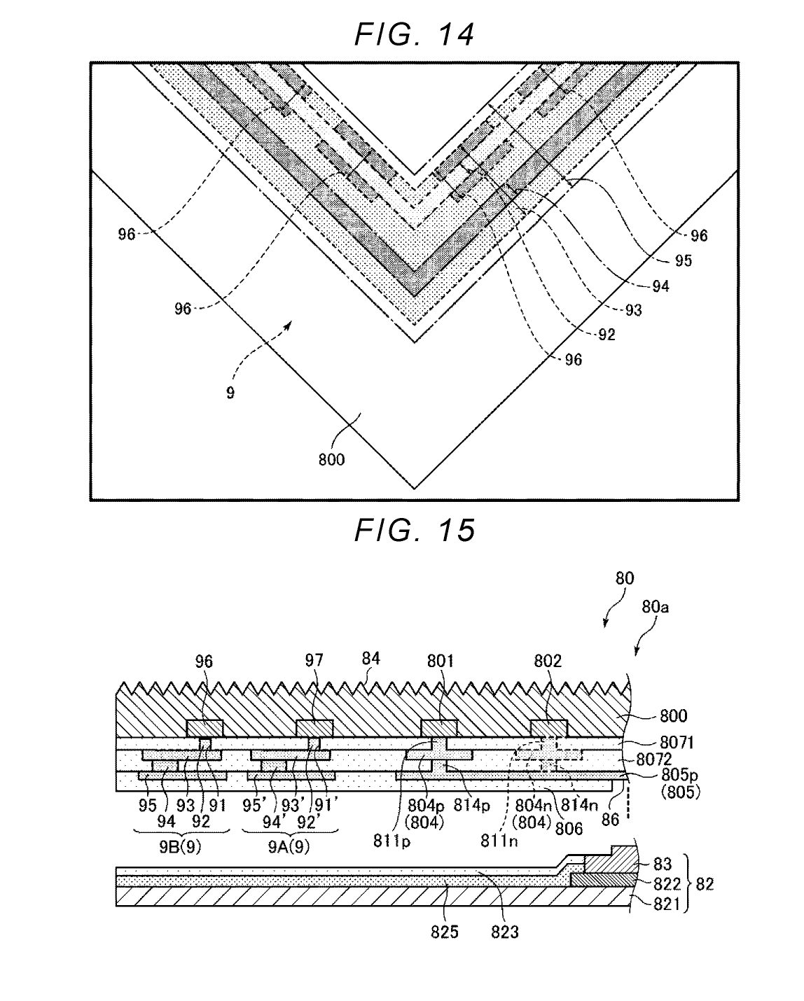

Next, the solar cell 80 to which the third embodiment of the photoelectric conversion module according to the invention is applied will be described in detail. FIG. 14 is a plan view showing a photoelectric conversion module according to the third embodiment.

Hereinafter, the third embodiment will be described, but in the following description, differences from the first embodiment will be mainly described, and matters similar to the first embodiment will not be repeated. In FIG. 14, the same reference numerals are given to the same configurations as those of the first embodiment described above.

The solar cell 80 according to the third embodiment is the same as the solar cell 80 according to the first embodiment except that the n-type high-concentration doping region 96 has a different shape.

That is, in the solar cell 80 according to the first embodiment, the n-type high-concentration doping region 96 continuously surrounds the power generating unit, whereas in the solar cell 80 according to the present embodiment, the n-type high-concentration doping region 96 intermittently surrounds the power generating unit, which is different from the solar cell 80 according to the first embodiment.

In other words, when the main surface of the Si substrate 800 is seen in a plan view, the n-type high-concentration doping region 96 is formed to intermittently surround the power generating unit provided with the p+ impurity region 801 and the n+ impurity region 802 and the like. Even with this configuration, the first plug layer 92 and the Si substrate 800 can be substantially equipotential across the entire moisture-proof structure 9, although it may be somewhat less than the first embodiment. As a result, moisture resistance of the cell 80a can be ensured.

In this case, the length of the discontinued portion is preferably equal to or less than 10%, or more preferably, equal to or less than 5% of the entire length of the periphery of the power generating unit. With this, even when the n-type high-concentration doping region 96 is discontinued, the first plug layer 92 and the Si substrate 800 can sufficiently be equipotential, so that an effect of suppressing corrosion of the first plug layer 92 and the like can be obtained. Also in the third embodiment as described above, effects similar to those of the first embodiment can be obtained.

### Fourth Embodiment

Next, the solar cell 80 to which the fourth embodiment of the photoelectric conversion module according to the invention is applied will be described in detail.

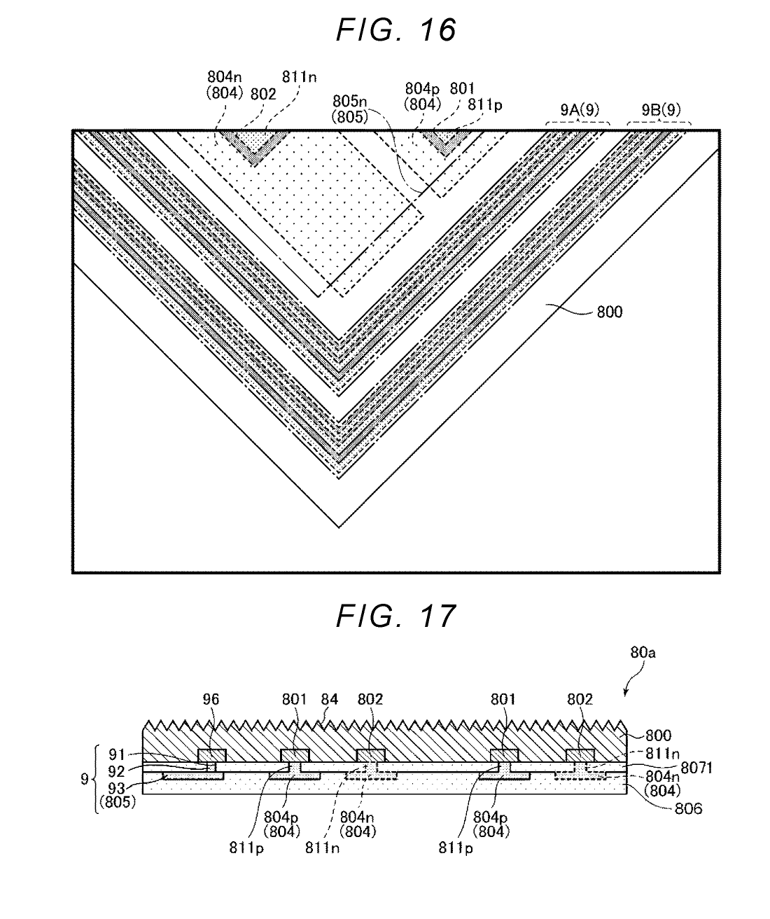

FIG. 15 is a cross-sectional view showing the photoelectric conversion module according to the fourth embodiment. FIG. 16 is a plan view showing a photoelectric conversion module shown in FIG. 15.

Hereinafter, the fourth embodiment will be described, but in the following description, differences from the first embodiment will be mainly described, and matters similar to the first embodiment will not be repeated. In FIGS. 15 and 16, the same reference numerals are given to the same configurations as those of the first embodiment described above.

The solar cell 80 according to the fourth embodiment is the same as the solar cell 80 according to the first embodiment except that the groove 91 and the first plug layer 92 are doubly provided.

That is, the moisture-proof structure 9 according to the fourth embodiment includes an inner moisture-proof structure 9A and an outer moisture-proof structure 9B which is positioned outside the inner moisture-proof structure 9A and has the same configuration as the moisture-proof structure 9 according to the first embodiment.

The inner moisture-proof structure 9A is provided inside the outer moisture-proof structure 9B. Accordingly, a multi-moisture-proof structure 9 is provided with the inner moisture-proof structure 9A and the outer moisture-proof structure 9B. With this configuration, the moisture-proof structure 9 can be formed in a redundant manner. As a result, even when manufacturing defects occur in either the inner moisture-proof structure 9A or the outer moisture-proof structure 9B, moisture resistance of the cell 80a can be ensured by compensating with the other one. Therefore, a more reliable solar cell 80 can be obtained.

The outer moisture-proof structure 9B shown in FIGS. 15 and 16 is the same as the moisture-proof structure 9 according to the first embodiment as described above.

That is, the outer moisture-proof structure 9B includes the groove 91 (the second groove), the first plug layer 92, the first another layer 93, the second plug layer 94, and the second another layer 95. Therefore, the description of the outer moisture-proof structure 9B will not be repeated.

Meanwhile, the inner moisture-proof structure 9A shown in FIG. 15 has the same configuration as the outer moisture-proof structure 9B except for having a p-type high-concentration doping region 97 in place of the n-type high-concentration doping region 96.

Specifically, the inner moisture-proof structure 9A includes a groove 91′ (the first groove), the first plug layer 92′, the first another layer 93′, the second plug layer 94′, and the second another layer 95′.

The configuration of the groove 91′, the first plug layer 92′, the first another layer 93′, the second plug layer 94′ and the second another layer 95′ of the inner moisture-proof structure 9A are the same as configuration of the groove 91, the first plug layer 92, the first another layer 93, the second plug layer 94, and the second another layer 95 of the outer moisture-proof structure 9B.

In addition, the p-type high-concentration doping region 97 is formed at a position facing the groove 91′ in the Si substrate 800. The p-type high-concentration doping region 97 is formed in the same manner as the p+ impurity region 801 described above, for example, and is a region doped with a p-type impurity at a high concentration.

To summarize the above, in the present embodiment, the groove 91′ (the first groove) and the groove 91 (the second groove) located outside the groove 91′ are included.

In addition, the first plug layer 92′ according to this embodiment is provided in the groove 91′, and the first plug layer 92 is provided in the groove 91.

In addition, the Si substrate 800 (semiconductor substrate) according to this embodiment has characteristics of an n-type semiconductor.

A portion facing the groove 91 (the second groove) of the Si substrate 800 is an n-type high-concentration doping region 96, and a portion facing the groove 91′ (the first groove) of the Si substrate 800 is a p-type high-concentration doping region 97.

In such a fourth embodiment, the n-type high-concentration doping region 96 and the p-type high-concentration doping region 97 are arranged adjacent to each other. Therefore, in the p-type high-concentration doping region 97, carriers can be generated by the light reception, likewise the electric power generating unit described above. That is, the generated holes can be collected in the first plug layer 92′ through the p-type high-concentration doping region 97. Meanwhile, generated electrons can be collected in the first plug layer 92 through the n-type high-concentration doping region 96. As a result, holes and electrons are separated, and a potential difference can be generated between the first plug layer 92 and the first plug layer 92′.

While not shown in FIGS. 15 and 16, the first plug layer 92 and the n-type bus bar electrode 805n (see FIG. 8) are electrically connected to each other, and the first plug layer 92′ and the p-type bus bar electrode 805p (see FIG. 8) are electrically connected to each other. As a result, the moisture-proof structure 9 can also be used for photoelectric conversion. As a result, in this embodiment, it is possible to further enhance the photoelectric conversion efficiency of the cell 80a while enhancing the moisture-proof function of the moisture-proof structure 9.

In addition, in the present embodiment, it is possible to efficiently trap both cations and anions contained in moisture. For example, when sodium chloride (NaCl) is contained in water, Na⁺, Cl⁻ are generated by ionization, but due to the electrostatic attraction, the cations are trapped in the first plug layer 92, and the anions are trapped in the first plug layer 92′. As a result, it is possible to suppress the arrival of cations and anions, which are one cause of corrosion, at the power generating unit, thereby more reliably suppressing the occurrence of corrosion.

When comparing the width of the n-type high-concentration doping region 96 (the length in the direction orthogonal to the extending direction of the outer moisture-proof structure 9B) and the width of the p-type high-concentration doping region 97 (the length in the direction orthogonal to the extending direction of the inner moisture-proof structure 9A), both may be approximately the same, or the width of the n-type high-concentration doping region 96 may be larger, or the width of the p-type high-concentration doping region 97 may be larger.

In addition, likewise the n-type high-concentration doping region 96, the p-type high-concentration doping region may be provided to continuously surround the power generating unit, and may be provided to intermittently surround the power generating unit.

In addition, the groove 91 and the first plug layer 92 may be provided in three or more layers. Also in the fourth embodiment as described above, effects similar to those of the first embodiment can be obtained.

### Fifth Embodiment

Next, the solar cell 80 to which the fifth embodiment of the photoelectric conversion module according to the invention is applied will be described in detail. FIG. 17 is a cross-sectional view showing a photoelectric conversion module according to the fifth embodiment.

Hereinafter, the fifth embodiment will be described, but in the following description, differences from the first embodiment will be mainly described, and matters similar to the first embodiment will not be repeated. In FIG. 17, the same reference numerals are given to the same configurations as those of the first embodiment described above.

In the solar cell 80 according to the first embodiment described above, the finger electrode 804 and the bus bar electrode 805 overlap with each other when the main surface of the Si substrate 800 is seen in a plan view. On the other hand, in the solar cell 80 according to the present embodiment, the finger electrode 804 and the bus bar electrode 805 are misaligned with each other. Thus, in this embodiment, it is possible to arrange the finger electrodes 804 and the bus bar electrodes 805 in the same layer. As a result, in the present embodiment, the layer configuration of the cell 80a is simplified, and manufacturing easiness can be enhanced.

Meanwhile, the moisture-proof structure 9 according to this embodiment includes the groove 91, the first plug layer 92, and the first another layer 93, while the interlayer insulating film 8072, the second plug layer 94 and the second another layer 95 according to the first embodiment are omitted. Therefore, since the number of laminated layers is small, ease of manufacturing can be enhanced.

Meanwhile, in the present embodiment, the first another layer 93 also serves as the bus bar electrode 805.

That is, the first another layer 93 serves not only as a barrier layer but also as a bus bar electrode 805. Therefore, as compared with the example where both the moisture-proof structure 9 and the bus bar electrode 805 are separately provided, it is possible to prevent the area of the cell 80a from becoming too large.

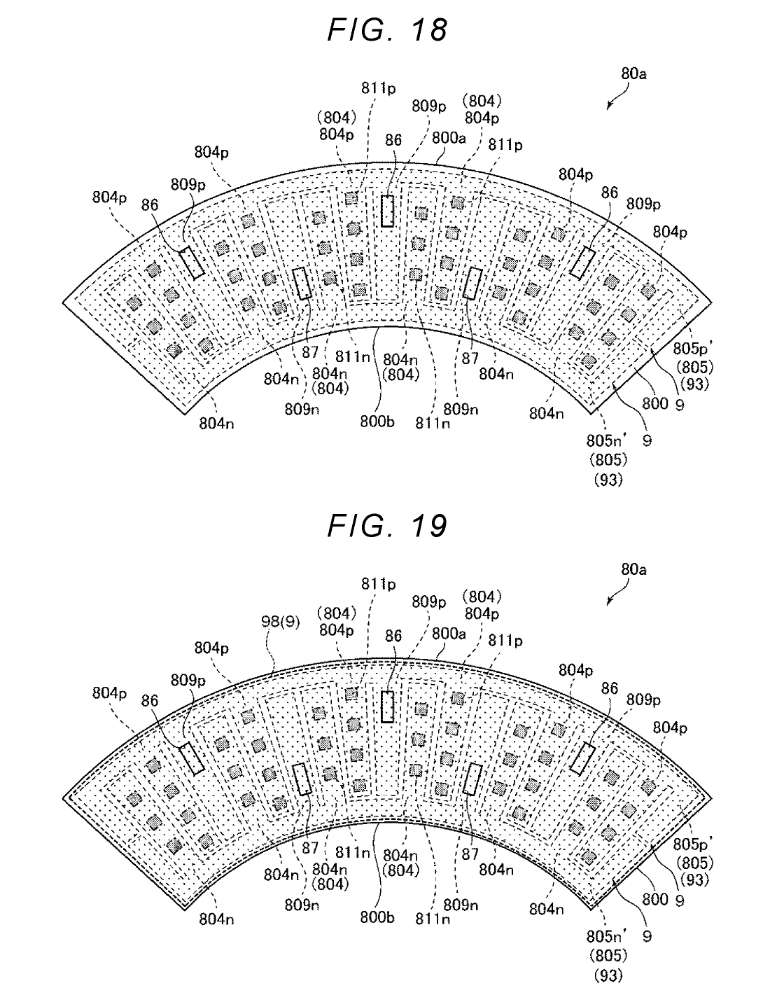

FIG. 18 is a plan view of the photoelectric conversion element shown in FIG. 17. The p-type bus bar electrode 805p′ shown in FIG. 18 is disposed at the same layer as the finger electrode 804 and is disposed closer to the substrate outer periphery 800a than the finger electrode 804.

Then, the p-type finger electrode 804p and the p-type bus bar electrode 805p′ are connected, while the n-type finger electrode 804n and the p-type bus bar electrode 805p′ are separated and isolated from each other.

Meanwhile, the n-type bus bar electrode 805n′ is disposed at the same layer as the finger electrode 804 and is disposed closer to the substrate inner periphery 800b than the finger electrode 804.

Then, then-type finger electrode 804n and the n-type bus bar electrode 805n′ are connected, while the p-type finger electrode 804p and the n-type bus bar electrode 805n′ are separated and isolated from each other.

In addition, the electrode pad 86 is provided at a position overlapping with a branch portion 809p branching off from the p-type bus bar electrode 805p′.

Meanwhile, the electrode pad 87 is provided at a position overlapping with the branch portion 809n branching off from the n-type bus bar electrode 805n′.

Therefore, the finger electrode 804 and the bus bar electrode 805 shown in FIG. 18 are in the form of a so-called comb-like electrode.

In addition, the p-type bus bar electrode 805p′ and the n-type bus bar electrode 805n′ are also separated and insulated. It is preferable that the separation distance is as small as possible within a range where the insulation property does not deteriorate. Thereby, it is possible to prevent the function of the moisture-proof structure 9 from being considerably deteriorated.

While not shown, the first plug layer 92 and the first another layer 93 of the present embodiment may be omitted. In that case, a portion of the passivation film 806 shown in FIG. 17 may be filled in the groove 91 in place of the first plug layer 92. As a result, a portion of the passivation film 806 serves as a barrier layer having a lower moisture permeability than the interlayer insulating film 8071. Therefore, even in such a case, the moisture-proof function of the moisture-proof structure 9 is secured. In this case, the passivation film 806 preferably includes silicon nitride. Also in the fifth embodiment as described above, effects similar to those of the first embodiment can be obtained.

In addition, FIG. 19 is a plan view showing a first modification of the photoelectric conversion element shown in FIG. 18. The first modification shown in FIG. 19 includes a moisture-proof structure 98 provided to surround the outside of the p-type bus bar electrode 805p′ and the n-type bus bar electrode 805n′ with respect to the cell 80a shown in FIG. 18. That is, the first modification shown in FIG. 19 is the same as the fifth embodiment shown in FIG. 18, except that a moisture-proof structure 98 is added.

It should be noted that, in FIG. 19, the moisture-proof structure 98 is shown by a dashed line for convenience of explanation, but the moisture-proof structure 98 according to the first modification is preferably provided in a continuous annular shape.

The moisture-proof structure 98 according to the first modification has the same configuration as the moisture-proof structure 9 according to the first embodiment described above. That is, the moisture-proof structure 9 according to the first modification includes both the moisture-proof structure 9 and the moisture-proof structure 98 shown in FIG. 17. Therefore, the cell 80a shown in FIG. 18 has a multi-structure. The first modification has an advantage of not only the small number of laminated layers according to the fifth embodiment described above, but also further improved moisture-proof function.

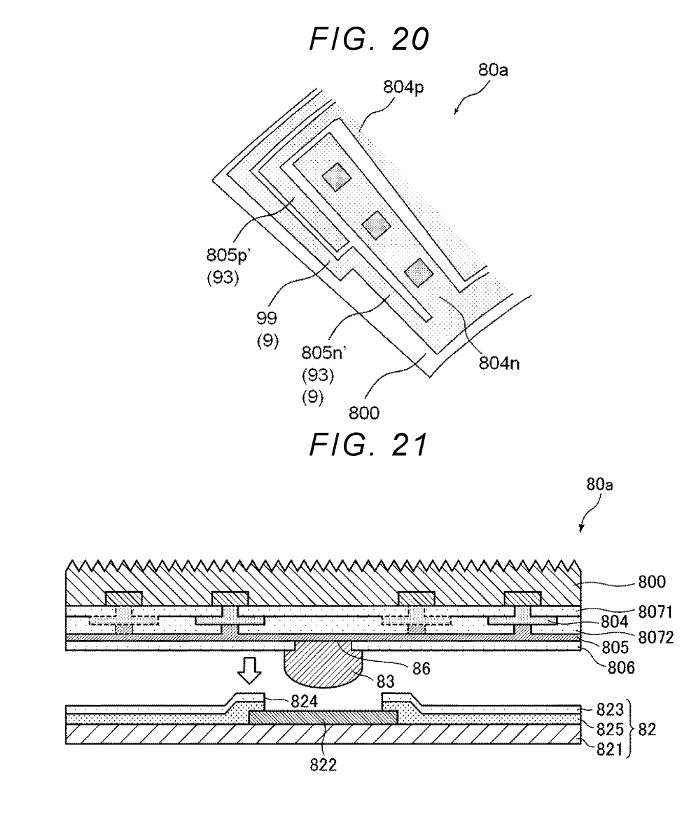

In addition, FIG. 20 is a plan view showing a portion of a second modification of the photoelectric conversion element shown in FIG. 18. The second modification shown in FIG. 20 is the same as the first modification shown in FIG. 19, except that the shape of the moisture-proof structure 9 is changed. Specifically, the second modification shown in FIG. 20 includes a moisture-proof structure 99 in place of the moisture-proof structure 98 shown in FIG. 19. The moisture-proof structure 99 is provided between the p-type bus bar electrode 805p′ and the outer periphery of the Si substrate 800. In addition, the moisture-proof structure 99 is connected to the n-type bus bar electrode 805n′. As a result, the n-type bus bar electrode 805n′ has also the moisture-proof function in addition to the function as the electrode described above. That is, since the n-type bus bar electrode 805n′ has a moisture-proof function in the first place, it is possible to omit a part of the moisture-proof structure 98 according to the first modification.

Also in such a second modification, the moisture-proof structure 99 and the n-type bus bar electrode 805n′ constitute a continuous annular moisture-proof structure 9.

Likewise the first modification, the second modification, has an advantage that the number of the laminated layers described above is small and the moisture-proof function is further improved. In addition, according to the second modification, since the n-type bus bar electrode 805n′ also has the moisture-proof function, it is possible to simplify the moisture-proof structure 9, and it is possible to further enhance the ease of manufacturing as compared with the first modification. Method of Manufacturing Photoelectric Conversion Module

Next, a method for manufacturing a solar cell 80 (photoelectric conversion module) will be described as an example.

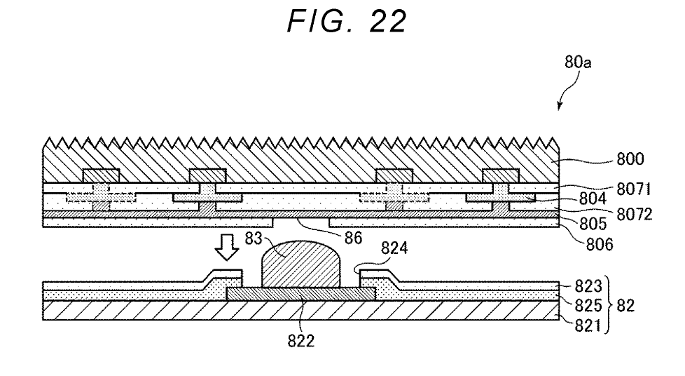

FIGS. 21 and 22 are views for explaining an example of a method for manufacturing the solar cell (photoelectric conversion module) shown in FIG. 7.

[1] First, a cell 80a is prepared. For example, the cell 80a is made by forming an impurity region or the like on a semiconductor wafer, followed by depositing an electrode, a contact, an insulating film, a moisture-proof structure, and the like, and then dividing into individual cells. For forming the electrodes, the contacts, the insulating film and the like, various vapor deposition techniques and a photolithography technique for patterning a film formed by the vapor deposition technique are used, for example. In addition, a moisture-proof structure can be formed simultaneously with these components.

[2] Next, the conductive connection portion 83 is disposed in at least one of the cell 80a and the opening 824. Specifically, as shown in FIG. 21, the conductive connection portion 83 may be disposed on the electrode pad 86 of the cell 80a, and as shown in FIG. 22, the conductive connection portion 83 may be disposed in the opening 824 of the wiring substrate 82. A metal bump or the like may be formed on the electrode pad 86 and the conductive film 822 in advance.

The conductive connection portion 83 shown in FIG. 21 is in contact with the electrode pad 86 of the cell 80a and is disposed to protrude downward in FIG. 21. Meanwhile, the conductive connection portion 83 shown in FIG. 22 is disposed to protrude upward in FIG. 22 inside the opening 824 of the wiring substrate 82. The conductive connection portion 83 disposed in this manner electrically connects the electrode pad 86 of the cell 80a and the conductive film 822 of the wiring substrate 82 to each other in the lamination step described below.

[3] Next, as shown in FIG. 21 or 22, the cell 80a and the wiring substrate 82 are overlapped with each other (laminating process) through the conductive connection portion 83.

Specifically, the cell 80a and the wiring substrate 82 are overlapped with each other, and then the cells 80a and the insulating film 823 are brought close to each other until they contact with each other. As a result, the conductive connection portion 83 deforms under the load and spreads in the space inside the opening 824. As a result, the conductive connection portion 83 contacts both the electrode pad 86 of the cell 80a and the conductive film 822 of the wiring substrate 82, and can electrically connect the electrode pad 86 of the cell 80a and the conductive film 822 of the wiring substrate 82 to each other. The solar cell 80 is obtained as described above.

Although the invention has been described based on the illustrated embodiments, the invention is not limited thereto.

For example, in the photoelectric conversion element, the photoelectric conversion module, and the electronic device according to the invention, a portion of the elements of the embodiment described above may be replaced by any element having the same function, and any elements may be added to the embodiment described above.

The entire disclosure of Japanese Patent Application No. 2018-040460, filed Mar. 7, 2018 is expressly incorporated by reference herein.

What is claimed is:

1. A photoelectric conversion element comprising:
a photoelectric conversion layer that has a p-type impurity region and an n-type impurity region;
an insulating layer that overlaps with the p-type impurity region and the n-type impurity region and has a groove outside the p-type impurity region and the n-type impurity region in a plan view of a main surface of the photoelectric conversion layer;
a p-type electrode electrically connected to the p-type impurity region;
an n-type electrode electrically connected to the n-type impurity region; and
a barrier layer that has a lower moisture permeability than the insulating layer, in the groove.

2. The photoelectric conversion element according to claim 1,
wherein the groove penetrates the insulating layer in a thickness direction.

3. The photoelectric conversion element according to claim 2,
wherein the photoelectric conversion layer has characteristics of an n-type semiconductor or a p-type semiconductor, and
when the photoelectric conversion layer has the characteristic of the n-type semiconductor, an n-type high-concentration doping region is provided in the photoelectric conversion layer adjacent to the barrier layer, and
when the photoelectric conversion layer has characteristic of the p-type semiconductor, a p-type high-concentration doping region is provided in the photoelectric conversion layer adjacent to the barrier layer.

4. The photoelectric conversion element according to claim 2,
wherein the groove has a first groove and a second groove located outside the first groove, and
the photoelectric conversion layer has a characteristic of a n-type semiconductor, a p-type high-concentration doping region adjacent to the barrier layer in the first groove, and an n-type high-concentration doping region adjacent to the barrier layer in the second groove.

5. The photoelectric conversion element according to claim 3,
wherein the n-type high-concentration doping region and the p-type high-concentration doping region surround the p-type impurity region and the n-type impurity region in a plan view of the main surface of the photoelectric conversion layer.

6. The photoelectric conversion element according to claim 4,
wherein the n-type high-concentration doping region and the p-type high-concentration doping region surround the p-type impurity region and the n-type impurity region in a plan view of the main surface of the photoelectric conversion layer.

7. The photoelectric conversion element according to claim 1,
wherein the barrier layer includes a metal material or silicon nitride.

8. The photoelectric conversion element according to claim 5,
wherein the barrier layer includes a metal material or silicon nitride.

9. The photoelectric conversion element according to claim 6,
wherein the barrier layer includes a metal material or silicon nitride.

10. The photoelectric conversion element according to claim 1,
wherein the p-type electrode, the n-type electrode and the barrier layer include the same material.

11. The photoelectric conversion element according to claim 1,
wherein the photoelectric conversion layer has mono-crystallinity.

12. A photoelectric conversion module comprising:
the photoelectric conversion element according to claim 1, and
a wiring substrate provided to overlap with the photoelectric conversion element.

13. An electronic device comprising:
the photoelectric conversion module according to claim 12.
